(19) United States
(12) Patent Application Publication
(10) Pub. No.: US 2026/0353630 A1
(43) Pub. Date: Nov. 5, 2026

(54) MEMORY CELL WITH TWO TRANSISTORS WITHOUT CAPACITOR, INTEGRATED INTO AN INTERCONNECT STACK

(71) Applicant: COMMISSARIAT A L'ENERGIE ATOMIQUE ET AUX ENERGIES ALTERNATIVES, Paris (FR)

(72) Inventor: Gabriel PARES, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/657,426

(22) Filed: Apr. 24, 2026

(30) Foreign Application Priority Data
Apr. 30, 2025 (FR) FR2504586

(51) Int. Cl. H10B 12/00; H10D 30/69

(52) U.S. Cl. CPC H10B 12/00; H10D 30/701

(57) ABSTRACT

The invention relates to an interconnect stack extending along to a main plane thereof, and comprising at least one memory cell of the 2T0C type. Each memory cell comprises: a cavity in the interconnect stack; a first conformal active portion made of a semiconductor material coating a sidewall and a bottom of the cavity; a read transistor and a write transistor respectively comprising a gate and a channel arranged in the cavity. The channel of the write transistor and the gate of the read transistor are formed in two separate regions of the first conformal active portion and are electrically connected to one another thereby.

### DESCRIPTION

### TECHNICAL FIELD

The field of the invention is that of interconnect stacks comprising a dynamic random access memory cell of the type 2T0C. The invention further relates to a method for manufacturing such a memory cell.

### PRIOR ART

Dynamic Random Access Memories (DRAM) are memories commonly used in the microelectronics industry and appreciated for their compactness. They can be embedded in a chip comprising an electronic circuit. They are then referred to as eDRAM, standing for “embedded DRAM”. This can have the advantage of reducing data access and/or write times, or lowering power consumption. For example, an eDRAM can be integrated into the substrate of the chip or into the interconnect stack thereof. In the latter case, it frees up space available for making transistors on and/or in the substrate.

A DRAM typically comprises a plurality of memory cells arranged in an array. Each memory cell stores a basic information unit or bit, in the form of an electrical charge. It is possible to write in one memory cell independently of the others, by means of two address lines, referred to as write lines, extending along rows or columns of the array. An address line, referred to as a write bit line, carries the basic information to be stored, typically a 1 or a 0. The other address line, referred to as the write word line, is intended to activate simultaneous writing in a row or column of memory cells. All the bits written in these memory cells constitute a word, sometimes referred to as a binary vector.

Similarly, the basic information stored in each memory cell is typically read by means of a read bit line and a read word line. The read word line is used to select a row or column of memory cells corresponding to a word. Each bit of the word is read on a separate read bit line.

In a particular architecture, referred to as the 1T1C architecture (one transistor, one capacitor), the bit lines and the word lines are shared for both reading and writing. The memory cell comprises a transistor controlling reading and writing, and which is electrically connected to a capacitor in which the information is stored.

The DRAM architecture known as the 2T0C architecture (two transistors, no capacitor) has recently been preferred over this architecture. The lack of capacitor facilitates its integration into the interconnect stack, in particular for the production of compact DRAMs comprising distributed memory cells in a three-dimensional array or 3D array. In this type of architecture, the read and write address lines are separate. Reading and writing in each memory cell are controlled respectively by a write transistor and a read transistor. The read transistor is a field-effect transistor. The intrinsic capacitance of its gate is used to store an electrical charge corresponding to the basic information.

To improve compactness, superimposing the read and write transistors has been proposed. In this case, they are typically connected by an interconnection level, which increases the complexity of the manufacturing process and can induce parasitic capacitances and/or resistances.

To further increase compactness, but also to benefit from other advantages, the use of gate-all-around (GAA) or channel-all-around (CAA) transistors has been proposed. A CAA transistor has a channel that completely encloses its gate. This configuration can be advantageous for increasing the source-drain current of the write transistor, which makes it possible to increase the write speed, and thus to increase the operating frequency of the eDRAM memory.

On the other hand, a GAA transistor has a gate that completely encloses its channel. This can be advantageous for increasing the intrinsic capacitance of the gate of the fixed-density read transistor and/or for minimizing the leakage current in the blocked state of the write transistor. The retention time of the stored electrical charge can thus be increased and the refresh rate of the memory cell decreased. When the GAA transistor is a vertical channel transistor, it occupies a smaller surface area compared to the surface area of the chip.

Patent document CN115568215 A illustrates an example of a memory cell of the 2T0C type in an interconnect stack. The channels of the read and write transistors are made of indium, gallium and zinc oxide (IGZO). For each memory cell, the write transistor is a vertical channel transistor of the GAA type. The channel thereof is cylindrical with an axis perpendicular to a main plane of the substrate. The gate of the read transistor comprises a metal storage node produced in an interconnection level between, on one side, the write address lines, and on the other side, the read address lines. This encloses the drain of the write transistor. The read transistor is a single-gate, planar field-effect transistor. Its channel extends parallel to the main plane of the substrate.

However, there is a limit beyond which the width of the channel of the write transistor cannot be increased without compromising its control. It is therefore not easy to increase its source-drain current when writing. The operating frequency of the DRAM 2T0C is therefore limited. Moreover, the storage node has parts facing address lines, in particular the read bit line and the write word line, which can induce parasitic capacitances disrupting memory operation. Finally, the manufacturing process is complex. Furthermore, such a memory cell has a structure that makes the interconnect stack not very compact vertically.

### DISCLOSURE OF THE INVENTION

The aim of the invention is to at least partially overcome the drawbacks of the prior art, and more particularly to propose an interconnect stack comprising a fast memory cell of the 2T0C type that limits parasitic effects, such as parasitic capacitances or resistances. Furthermore, the method for manufacturing such an interconnect stack is simplified.

For this purpose, the object of the invention is an interconnect stack comprising at least one memory cell of the 2T0C type. Each memory cell comprises a cavity in the interconnect stack, a first conformal active portion made of a semiconductor material coating a sidewall and a bottom of the cavity, a read transistor and a write transistor respectively comprising a gate and a channel, arranged in the cavity, the channel of the write transistor and the gate of the read transistor being formed in two separate regions of the first conformal active portion and electrically connected to one another by the first conformal active portion.

Some preferred, yet non-limiting, aspects of this interconnect stack are as follows.

The channel of the write transistor can extend continuously over the sidewall of the cavity so as to form a ribbon winding about itself.

The interconnect stack can further comprise a write word line which can extend parallel to a main plane of the interconnect stack. A gate of the write transistor can be formed in a region of the write word line surrounding the cavity.

The interconnect stack can further comprise a first read address line which can extend parallel to the main plane. The memory cell can comprise a second conformal active portion made of a semiconductor material and divided into an inner part and an outer part, which are respectively arranged inside and outside the cavity. A channel of the read transistor can be formed in the inner part and can be electrically connected to the first read address line by the outer part.

The inner part can have a cuvette shape that conforms to the shape of the sidewall of the cavity at the channel of the read transistor and can define, together with the bottom and the sidewall of the cavity, a closed so-called separation volume, which can be arranged facing the channel of the write transistor.

The gate of the read transistor can extend continuously over the sidewall of the cavity so as to form a ribbon wound about itself.

The interconnect stack can further comprise a second read address line which can extend parallel to the main plane, and which can be electrically connected to the channel of the read transistor through the inner part and a central via which can pass through an opening made in the first read address line.

The first read address line can be in contact with the outer part on an electrical contact area thereof, surrounding the cavity.

A source and a drain of the read transistor can be formed in two separate regions of the outer part, which can be separated from each other by the inner part. The gate of the read transistor can coat the bottom of the cavity.

A source of the write transistor can be a region of the first conformal active portion that can extend continuously over the sidewall of the cavity so as to form a ribbon wound about itself.

The write transistor can be a ferroelectric field-effect transistor.

The invention further relates to a method for manufacturing an interconnect stack according to any one of the preceding features, comprising a step of providing an intermediate structure comprising a first conductive line and a second conductive line extending in separate parallel planes of the intermediate structure; a step of forming the cavity in the intermediate structure, through the first conductive line; a step of conformally depositing a first conformal dielectric layer on the sidewall and the bottom of the cavity; a step of conformally depositing a first conformal semiconductor layer on the first conformal dielectric layer; a step of locally removing the first conformal semiconductor layer in order to retain a residual portion facing the bottom and the sidewall of the cavity forming the first conformal active portion; a step of forming the channel of the write transistor in the first conformal active portion facing the first conductive line; and a step of forming the gate of the read transistor in the first conformal active portion.

The step of forming the cavity can comprise one of the following sub-steps: etching an opening through the first conductive line, which can extend depthwise into the intermediate structure from an upper face thereof; selectively etching a lateral recess in the first conductive line from the opening.

The first conformal dielectric layer can be etched anisotropically before the step of conformally depositing the first conformal semiconductor layer in order to retain a residual portion protected by the lateral recess which can thus form a gate dielectric of the write transistor.

The cavity can result from etchings of the opening and the lateral recess. The method can further comprise one of the following steps: depositing a filler material in the cavity so as to cover the channel of the write transistor; partially etching the filler material to retain a separation volume facing the channel of the write transistor; successively carrying out the conformal depositions of a second conformal dielectric layer and of a second conformal semiconductor layer in the cavity and on the separation volume; forming a gate dielectric and a channel of the read transistor in respective regions of the second conformal dielectric layer and of the second conformal semiconductor layer facing the sidewall of the cavity and delimited by the separation volume.

The cavity can result from the etchings of the opening and of the lateral recess, and the method can further comprise one of the following steps: depositing a first planarizing layer in the cavity so as to cover same; etching a secondary cavity capable of passing all the way through the first planarizing layer to reach the bottom of the cavity; conformally depositing a second conformal semiconductor layer on an upper face of the first planarizing layer, in the secondary cavity and on the bottom of the cavity; delimiting, by etching, a second conformal active portion in the second conformal semiconductor layer, which can extend continuously between two regions of the second conformal semiconductor layer located on either side of the bottom of the cavity, so as to receive therein respectively a source and a drain of the read transistor.

### BRIEF DESCRIPTION OF THE DRAWINGS

Other aspects, aims, advantages and features of the invention will become more apparent upon reading the following detailed description of preferred embodiments thereof, provided by way of non-limiting example, and made with reference to the appended drawings wherein:

FIG. 1 groups together diagrammatic views of a first embodiment of an interconnect stack containing a memory cell according to the invention;

FIG. 2 is a diagrammatic perspective high view of the first embodiment in the case where the interconnect stack comprises a plurality of memory cells arranged in an array;

FIG. 3 groups together diagrammatic views of a second embodiment of an interconnect stack containing a memory cell according to the invention;

FIG. 4 is a diagrammatic perspective high view of the second embodiment in the case where the interconnect stack comprises a plurality of memory cells arranged in an array;

FIGS. 5A-5Q are diagrammatic views of steps of a first manufacturing method of the first embodiment;

FIGS. 6A-6H are diagrammatic views of steps of a second manufacturing method of the second embodiment.

### DETAILED DISCLOSURE OF PARTICULAR EMBODIMENTS

In the figures and in the following description, the same references represent identical or similar elements. Furthermore, the different elements are not represented to scale so as to favor clarity of the figures. Moreover, the different embodiments and alternatives are not mutually exclusive and can be combined together. Unless stated otherwise, the terms “substantially”, “about”, and “in the range of” mean within a 10% margin, and preferably within a 5% margin. Moreover, the terms “between … and …” and equivalents mean that the bounds are included, unless specified otherwise.

The invention relates to an interconnect stack comprising at least one memory cell of the 2T0C type. Each memory cell comprises a cavity, a first conformal active portion made of a semiconductor material coating a sidewall and a bottom of the cavity, a read transistor and a write transistor. The channel of the write transistor and the gate of the read transistor are arranged in the cavity, formed in two separate regions of the first conformal active portion, and electrically connected to one another thereby.

This arrangement allows the channel of the write transistor to be brought closer to the gate of the read transistor, while doing away with the need for an interconnection level. As a result, the memory cell is compact and parasitic electrical effects are reduced. The absence of an interconnection level facilitates the manufacturing process.

Furthermore, the channel of the write transistor can extend continuously over the sidewall of the cavity so as to form a ribbon wound about itself. Thus, the width of the write transistor, which is defined by the length of the perimeter of the cavity, allows a strong source/drain current to pass through the write transistor. This reduces the writing time.

Other advantages of the invention will appear upon reading the detailed description of the particular embodiments below.

The term “layer” is understood herein to mean an area consisting of one or more sublayers of a material of which the thickness, along a local z-axis is less than, for example ten times less than, or even twenty times less than, the longitudinal width and length dimensions thereof in a plane (x, y) perpendicular to the z-axis. A layer can be patterned, or have a structure that has a substantially constant thickness extending for the most part along a main plane. When it consists of a plurality of sublayers, the sublayers can be made of different materials. The one or more sublayers extend in planes substantially parallel to the plane (x, y). When a layer has a property, it is understood that when it consists of a plurality of sublayers, all the sublayers have the same property, unless explicitly stated otherwise. As an example, unless further specified, a layer made of metal, made of a semiconductor material, or a layer that is amorphous can comprise a plurality of sublayers, all respectively made of metal, made of a semiconductor material, or all amorphous. A layer can be conformal, which implies that it extends over a surface, for example a non-planar surface, and that it conforms to the shape of this surface. A conformal layer has a thickness, measured perpendicularly to the surface to which it conforms, that is substantially constant, for example to within 10%, or even to within 5%. An interlayer dielectric is a dielectric layer of an interconnect stack, receiving electrically conductive lines and/or conductive vias.

A layer can comprise one or more portions, the thickness of each portion extending from one face to another, opposite face of the layer. A layer can be etched locally all the way through to form one or more portions. The portion inherits the layer’s properties. It can thus be conformal if the layer is conformal. Where relevant, it meets the thickness criterion defined for the conformal layer.

Particular embodiments will be described, integrating a memory cell capable of storing a basic information unit. Examples of arrangements in an array are given by way of example for storing words of a plurality of basic information units. However, various arrangements can be envisaged, for example address lines can form any angle with the rows and columns of the array, memory cells storing a word can be arranged on various levels of the interconnect stack, etc. A plurality of memory cell arrays can be stacked on top of each other.

In all figures, embodiments are represented according to idealized geometric shapes, it being understood that the corresponding realized shapes can undergo modifications compatible with the invention, due to limitations of the manufacturing method, such as a lack of resolution, alignment uncertainties or etch slopes.

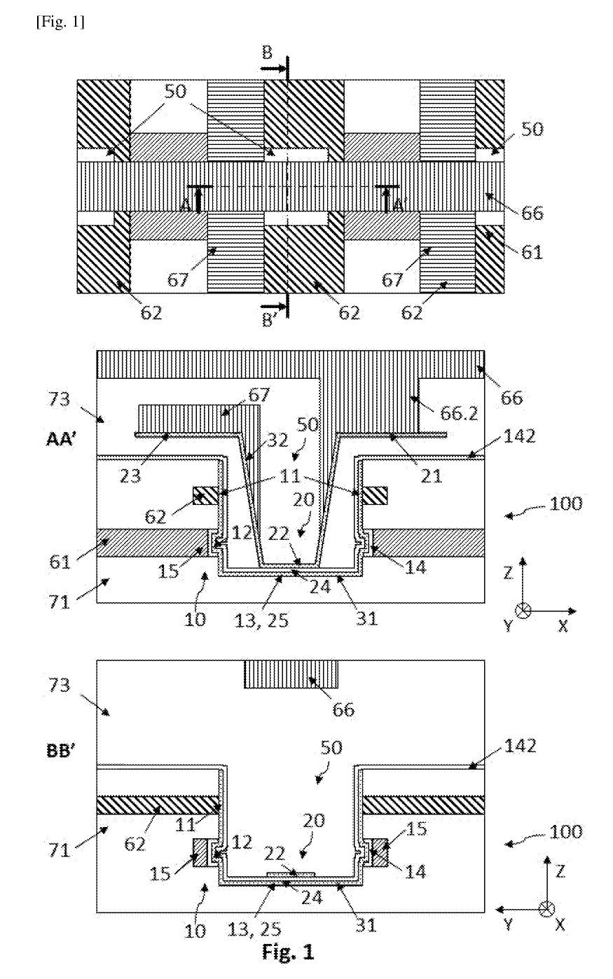

A first embodiment of an interconnect stack 100 according to the invention will now be described with reference to FIG. 1. The top of this drawing shows a top view, the middle of this drawing shows a view along the cutting plane A-A’ referenced in the top view, and the bottom of this drawing shows a view along the cutting plane B-B’, also referenced in the top view. Only the address lines of the memory cell are shown in the top view. The sectional views do not show the elements in the background. The top view shows a memory cell in an array comprising a plurality of identical memory cells. This is surrounded by two partial views of adjacent and identical memory cells, located on the same row of the array.

The interconnect stack 100 rests on a substrate that is not shown. It extends parallel to a main plane and to an upper face of the substrate. The substrate can be a plate, for example made of silicon and that is optionally cut and/or thinned. It can comprise electronic or photonic components, such as transistors or waveguides for example. Furthermore, at least one interconnection level can be present above the substrate between the electronic or photonic components and the memory cells, allowing these components to be interconnected and connected to outside the stack.

An orthogonal three-dimensional direct reference frame (X, Y, Z) is defined here and for the remainder of the description, wherein the axes X and Y form a plane parallel to the upper face of the substrate and to the main plane of the interconnect stack 100, the X-axis being oriented parallel to the cutting plane A-A’, the Y-axis being oriented parallel to the cutting plane B-B’, and wherein the Z-axis is oriented substantially orthogonally to the main plane, from the substrate to the interconnect stack 100. In the remainder of the description, the terms “vertical” and “vertically” are understood as relating to an orientation substantially parallel to the Z-axis, and the terms “horizontal” and “horizontally” as relating to an orientation substantially parallel to the plane (X, Y). Furthermore, the terms “lower” and “upper” are defined as relating to an increasing position when moving in the direction +Z. The term “lateral” refers to an orientation substantially parallel to the Z-axis. A “top view” is a view in the direction -Z.

The interconnect stack 100 comprises a memory cell. The memory cell comprises a cavity 50. The interconnect stack 100 comprises a lower dielectric stack 71, an upper dielectric stack 73, and a set of four address lines of the memory cell consisting of a write word line 61, a write bit line 62, a read bit line 67, and a read word line 66. The write word line 61, the write bit line 62, the read bit line 67 and the read word line 66 successively extend in the direction +Z in separate planes parallel to the main plane. The read word and bit lines 66, 67 can be swapped.

The address lines are made of an electrically conductive material, in this case metal. The write word and bit lines 61, 62 extend in the lower dielectric stack 71. The read word and bit lines 66, 67 extend in the upper dielectric stack 73. The upper dielectric stack 73 is in contact with the lower dielectric stack 71 via a second conformal dielectric layer 142. For example, the write word and bit lines 61, 62 are located below the read word and bit lines 66, 67 along the Z-axis perpendicular to the main plane (X, Y).

The lower and upper dielectric stacks 71, 73 are made of one or more dielectric materials. Examples of structures of these stacks are given below, in the detailed description of methods for manufacturing the invention.

The cavity 50 extends depthwise in the lower dielectric stack 71 from an upper face thereof. It has a sidewall and a bottom. The sidewall in this case consists of four walls, substantially orthogonal in pairs, and parallel to the planes (X, Z) or (Y, Z). The bottom in this case is substantially planar and parallel to the plane (X, Y). The cavity therefore has a parallelepipedal shape here. However, other shapes may be suitable. For example, it can have a cylindrical shape or comprise more or fewer walls. The bottom of the cavity may be non-planar.

In this case, the cavity 50 has a substantially square horizontal cross-section with a side measuring between 50 nm and 500 nm. When the walls of the cavity 50 are inclined, the length of one side of the cavity is measured at the bottom thereof.

The write word and bit lines 61, 62 surround the cavity 50 at the sidewall thereof, i.e. the cavity 50 crosses the write word and bit lines 61, 62. The write word line 61 in this case comprises a lateral recess forming a closed loop at the sidewall of the cavity 50. In other words, the sidewall of the cavity comprises a notch indented into the lower dielectric stack 71 at the write word line 61, the latter opening into the cavity 50 at this notch. The notch travels around the cavity in the same plane as that in which extends the write word line 61.

The notch has, for example, a horizontal depth of between 10 nm and 30 nm.

The write bit line 62 opens into the cavity 50 at the sidewall thereof. The part of the write bit line 62 thus exposed in the cavity 50 defines a contact edge. The contact edge travels around the cavity and is wound around itself in a horizontal plane. It is substantially aligned with the lower dielectric stack 71 in this case.

The memory cell comprises a write transistor 10 and a read transistor 20. The write transistor 10 has a gate dielectric 14 housed in the notch in the sidewall of the cavity 50, in contact with the write word line 61. The gate dielectric 14 is made of a dielectric material. It can be made of SiO₂, HfO₂, ZrO₂, HfSiO, HfON, Al₂ O₃ or a combination thereof. Advantageously, as is the case here, it is a HfO₂/Al₂O₃ bilayer in order to have good control over the threshold voltage of the write transistor 10. For example, the gate dielectric 14 has a thickness measured in the plane (X, Y) that is strictly less than the recess of the write word line 61, for example between 2 nm and 15 nm. Where relevant, the notch is partially filled by the gate dielectric 14.

The sidewall and the bottom of the cavity 50 are coated with a first conformal active portion 31. When the gate dielectric 14 partially fills the notch in the sidewall of the cavity 50, the first conformal active portion 31 conforms to the shape of the free part thereof. A region of the first conformal active portion 31, in contact with the gate dielectric 14, constitutes a channel 12 of the write transistor 10. Advantageously, as shown in FIG. 1, the first conformal active portion 31 substantially covers the entire sidewall and bottom of the cavity 50.

The first conformal active portion 31 is made of a semiconductor material, for example indium-gallium-zinc oxide (IGZO), indium-zinc oxide (IZO), indium-tungsten oxide (IWO), indium-tin oxide (ITO), In₂O₃, or ZnO. It can also be made of a transition-metal dichalcogenide (TMD), such as MoS₂ or WSe₂ for example. It can also be made of an organic semiconductor. The first conformal active portion 31 has, for example, a thickness of between 1.5 nm and 10 nm. A first conformal active portion 31 made of semiconductor oxide allows the leakage current of the write transistor 10 to be reduced, thus increasing the retention time.

The second conformal dielectric layer 142 extends continuously over the upper face of the lower dielectric stack 71, the sidewall and the bottom of the cavity 50. It covers the first conformal active portion 31 at the sidewall and bottom of the cavity 50, such that it is in contact therewith. It is made of a dielectric material, for example SiO₂, HfO₂, ZrO₂, HfSiO, HfON, Al₂O₃ or a combination thereof. It advantageously has a ferroelectric property. In this case, it can be made of Hf₁₋ₓZrₓO₂, where x is between 0.2 and 0.8. For example, it has a thickness between 2 nm and 15 nm.

The write transistor 10 has a gate 15. The gate 15 is a region of the write word line 61 that opens into the cavity 50 at the notch. It is in contact with the gate dielectric 14 over the entire perimeter of the cavity 50. Advantageously, the gate 15 of the write transistor 10 extends along the Z-axis perpendicularly to the main plane (X, Y).

The write transistor 10 has a source 11 located in a region of the first conformal active portion 31 that is in contact with the sidewall of the cavity 50. The source 11 is electrically connected to the write bit line 62 by its contact edge. It travels around the cavity 50 and is wound about itself in a horizontal plane.

The write transistor 10 has a drain 13 located in a region of the first conformal active portion 31 that is opposite the source 11 with respect to the channel 12. The drain 13 extends around the perimeter of the cavity 50 and can be in contact with the bottom of the cavity 50. The source 11, the channel 12 and the drain 13 of the write transistor 10 can be doped or non-doped.

The memory cell comprises a second conformal active portion 32. The second conformal active portion 32 is divided into an inner part and an outer part, which are respectively arranged inside and outside the cavity 50. It extends in the upper dielectric stack 73, from two regions thereof which are opposite with respect to the cavity 50 when viewed from above, and which are located facing the upper face of the lower dielectric stack 71. In this example, it has a rectangular shape when projected onto the plane (X, Y), the sides whereof are parallel to the X- or Y-axis. According to this projection, the second conformal active portion 32 is, in this case, centered on the cavity 50. It has a width measured parallel to Y that is strictly less than the width of the cavity 50 measured along the same axis at the bottom of the cavity, and a projected length along the X-axis that is strictly greater than the width of the cavity 50 measured along X at its upper part.

The second conformal active portion 32 is in contact with the bottom of the cavity 50 via the second conformal dielectric layer 142 and via the first conformal active portion 31. The regions facing the first conformal active portion 31 and the second conformal active portion 32, at this physical contact area, respectively define a gate 25 and a channel 22 of the read transistor 20. The gate 25 of the read transistor 20 is thus electrically connected to the channel 12 of the write transistor 10 via a portion of the first conformal active portion 31 that includes the drain 13 of the write transistor 10. The connection between the write transistor 10 and the gate 25 of the read transistor 20 is thus simplified. It is compact and does not require an additional interconnection level. The gate 25 can be at least partially included in the drain 13 of the write transistor 10.

The second conformal active portion 32 is made of a semiconductor material, for example polycrystalline silicon, indium-gallium-zinc oxide (IGZO), indium-zinc oxide (IZO), indium-tungsten oxide (IWO), indium-tin oxide (ITO), In₂O₃, or ZnO. It can also be made of a transition-metal dichalcogenide (TMD), such as MoS₂ or WSe₂ for example. It can also be made of an organic semiconductor. The second conformal active portion 32 has, for example, a thickness between 1.5 nm and 10 nm.

The read bit line 67 is in contact with the second conformal active portion 32. The contact area defines a first electrical contact area of the second conformal active portion 32 which extends over the outer part thereof, over a planar part and parallel to the plane (X, Y). Alternatively, it can be in contact with this first electrical contact area through an electrically conductive via. Thus, the channel 22 of the read transistor 20 is electrically connected to the read bit line 67 via the second conformal active portion 32. In this example, the read transistor 20 has a drain 23 located in the second conformal active portion 32 between the channel 22 and the first electrical contact area.

Preferably, the first electrical contact area further extends over the inner part of the second conformal active portion 32, over a first inclined part thereof, which is inclined relative to the Z-axis. Thus, the distance between the channel 22 and the first electrical contact area is reduced. This is all the more advantageous when the second conformal active portion 32 is made of a highly resistive material, as is the case with a semiconductor oxide. The first electrical contact area can extend continuously from the outer part, towards the bottom of the cavity 50, for example until reaching the channel 22 of the read transistor 20. Where relevant, the first inclined part of the inner part makes a non-zero angle with the Z-axis, for example an angle of between 1° and 20°, or between 5° and 20°, or even an angle of less than 10°. This inclination of the inner part makes it easier to produce the read bit line 67, and to obtain good electrical contact between the read bit line 67 and the second conformal active portion 32.

The read word line 66 is in contact, in this case through an optional lateral via 66.2, with the second conformal active portion 32, on a second electrical contact area thereof. The second electrical contact area is planar and parallel to the plane (X, Y) at the outer part of the second conformal active portion 32. The second electrical contact area is located on one side of the second conformal active portion 32, opposite the first electrical contact area, with respect to the cavity 50 and to the channel 22 of the read transistor 20. Thus, the channel 22 of the read transistor 20 is electrically connected to the read word line 66 via the second conformal active portion 32. In this example, the read transistor 20 has a source 21 located in the second conformal active portion 32 between the channel 22 and the second electrical contact area.

Preferably, the second electrical contact area extends over the inner part of the second conformal active portion 32, over a second inclined part thereof, which is inclined relative to the Z-axis. Thus, the distance between the second electrical contact area and the channel 22 of the read transistor 20 is reduced. The second electrical contact area can extend continuously from the outer part, towards the bottom of the cavity 50, for example until reaching the channel 22 of the read transistor 20. Where relevant, the second inclined part of the inner part makes a non-zero angle with the Z-axis, for example an angle of between 1° and 20°, or between 5° and 20°, or even an angle of less than 10°. This inclination of the inner part makes it easier to produce the word bit line 66, and to obtain good electrical contact between the lateral via 66.2 and the second conformal active portion 32.

In this case, the first and second contact areas extend in the same horizontal plane; nonetheless, they can be arranged in separate planes. The part of the second conformal dielectric layer 142 in contact with the channel 22 and the gate 25 of the read transistor 20 at the bottom of the cavity 50, constitutes a gate dielectric 24 of the read transistor 20.

When the gate dielectric 24 is made of a ferroelectric material, it constitutes a storage node for storing a basic information unit, recorded in the form of a polarization direction of the material. The read transistor 20 is thus a ferroelectric field-effect transistor, also referred to as FeFET.

When the gate dielectric 24 is not ferroelectric, the storage node consists of the gate 25 of the read transistor 20. Where relevant, the basic information unit is stored in the form of electrical charges.

Examples will now be given of particular dimensions. The cavity 50 can have a depth measured parallel to the Z-axis, of between 70 nm and 250 nm. A reduced depth of the cavity 50 makes it possible to decrease the dimensions of the source 21 and the drain 23, and thus reduce an access resistance in the read transistor 20. The write word line 61 can have a thickness measured parallel to the Z-axis, of between 10 nm and 50 nm. The write bit line 62 can have a thickness measured parallel to the Z-axis, of between 10 nm and 50 nm. The write word and bit lines 61, 62 can be separated along the Z-axis by a distance of between 10 nm and 50 nm. The horizontal widths of the write word and bit lines 61, 62 can be between 100 nm and 500 nm. The dimensions of the read word and bit lines 66, 67 can be chosen in the same corresponding ranges of the write bit line 62. The length of the channel 22 of the read transistor 20, measured parallel to the Y-axis, can be between 30 nm and 100 nm. The width of the channel 22, measured parallel to the X-axis, can be between 12 nm and 50 nm.

The write word line 61 can be made of titanium nitride (TiN) or tungsten nitride (WN) or of any other electrically conductive material suitable for the gate electrode function of a transistor. The write bit line 62 is made of a metal that is different from that of the write word line 61, for example that has a lower electrical resistivity. It is, for example, made of ruthenium (Ru), or molybdenum (Mo), or any other electrically conductive material suitable for the source electrode function of a transistor, the latter advantageously being of the semiconductor oxide channel type. The read word and bit lines 66, 67 can be made of the same materials that are possible for the write word and bit lines 61, 62, or from other metals, such as copper (Cu) or an aluminum-copper alloy (AlCu). Each of these address lines can be coated with layers of other materials, having, for example, properties making it possible to reduce the contact resistances with the material of the channels 12 and 22 and also as diffusion barrier layer and/or bonding layer.

In operation, in the case where the gate dielectric 24 is not ferroelectric, the memory cell stores a basic information unit in the form of electrical charges in the storage node consisting of the gate 25 of the read transistor 20. During a write phase, the gate 15 of the write transistor 10 is activated by the write word line 61, allowing electrical charges corresponding to the basic information unit to be transferred from the write bit line 62 to the storage node, via the channel 12 of the write transistor 10. The electrical charges are transferred to the gate 25 of the read transistor 20 by the first conformal active portion 31.

During a read phase, a non-zero electrical potential difference, applied by the read word and bit lines 66, 67, between the source 21 and the drain 23 of the read transistor 20 is sufficient to conduct an electrical current S/D in the channel 22 thereof, when a basic information unit is stored in the storage node. The electrical current S/D is detected or measured. It depends on the state of charge of the storage node, thus making it possible to return the basic information unit stored, which can be analog or digital.

This read phase is non-destructive, i.e. it does not change the state of charge of the storage node. On the other hand, due to leakage currents, in particular through the channel 12 of the write transistor 10, periodic refreshes may be necessary. A gate dielectric 24 of the read transistor 20 made of a ferroelectric material makes it possible to increase the retention time of the basic information unit, which allows for less frequent refreshes, or even to do away with the need therefor. Where relevant, the second conformal dielectric layer 142 is itself made of a ferroelectric material.

When the gate dielectric 24 is ferroelectric, the source 21 and/or the drain 23 of the read transistor 20 is polarized to an electrical potential making it possible to orient the electrical polarization of the gate dielectric 24 in two opposite directions depending on the electrical potential applied to the source 11 of the write transistor 10, when the latter is conducting. The orientation of the polarization of the gate dielectric 24 influences the threshold voltage of the read transistor 20. Thus, the basic information unit present at the source 11 of the write transistor 10 in the form of an electrical potential is stored in the gate dielectric 24 in the form of an orientation of its electrical polarization. During the read phase, the electrical current S/D depends on the value of the threshold voltage of the read transistor 20. It is therefore possible to return the stored basic information unit. This phase does not destroy the stored information.

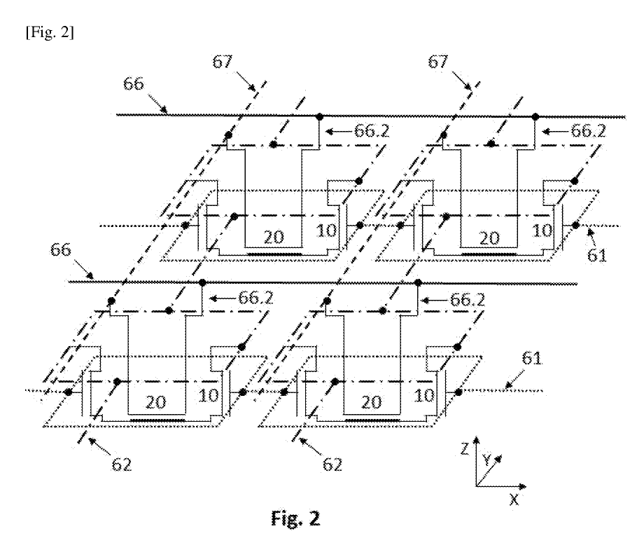

An advantageous arrangement of memory cells in an array will now be described, with reference to FIG. 2. This figure very diagrammatically shows four memory cells of the array, along the cutting plane A-A’ in FIG. 1. For better legibility, elements located in separate planes, perpendicular to the Z-axis, are represented using lines with different patterns. Dotted lines, mixed dash-dot lines, dashed lines and solid lines can thus be seen in the increasing Z-direction. Some electrical connections are diagrammatically shown as a solid disk.

In this array, the write and read word lines 61, 66 extend parallel to the X-axis. For each row of the array, a write word line 61 surrounds the cavities 50 of the memory cells of the row. Each read word line 66 addresses all the memory cells of a row of the array through a corresponding lateral via 66.2.

The write and read bit lines 62, 67 extend parallel to the Y-axis. For each column of the array, a write bit line 62 surrounds the cavities 50 of the memory cells of the column. Each read bit line 67 addresses all the memory cells of a column of the array, through a via, or directly in contact with the outer part of the second conformal active portion 32 of each memory cell.

Thus, each memory cell is located, on the one hand, at the intersection of a read word line 66 and a read bit line 67 and, on the other hand, at the intersection of a write word line 61 and a write bit line 62. In operation, during a write phase, the activation of a write word line 61 selects the memory cells arranged in the corresponding row of the array, i.e. an electrical potential applied to the write word line 61 renders the write transistors 10 of the memory cells arranged in this row conducting. Electrical charges carried on the write bit lines 62 are then transferred to the gates 25 of the selected memory cells only.

During a read phase, the read bit lines 67 are maintained at a reference electrical potential, for example ground. All the read word lines 66 are maintained at the reference electrical potential, with the exception of a single read word line selecting a row of memory cells. This is brought to an electrical potential that allows an electrical current S/D to be generated between the source 21 and the drain 23 of the read transistor 20 of each selected memory cell, depending on the electrical charge stored on the storage node, or the electrical polarization thereof. Each electrical current S/D is measured or detected on a corresponding read bit line 67, which makes it possible to simultaneously read the basic information units stored in all the selected memory cells, each on a separate read bit line 67.

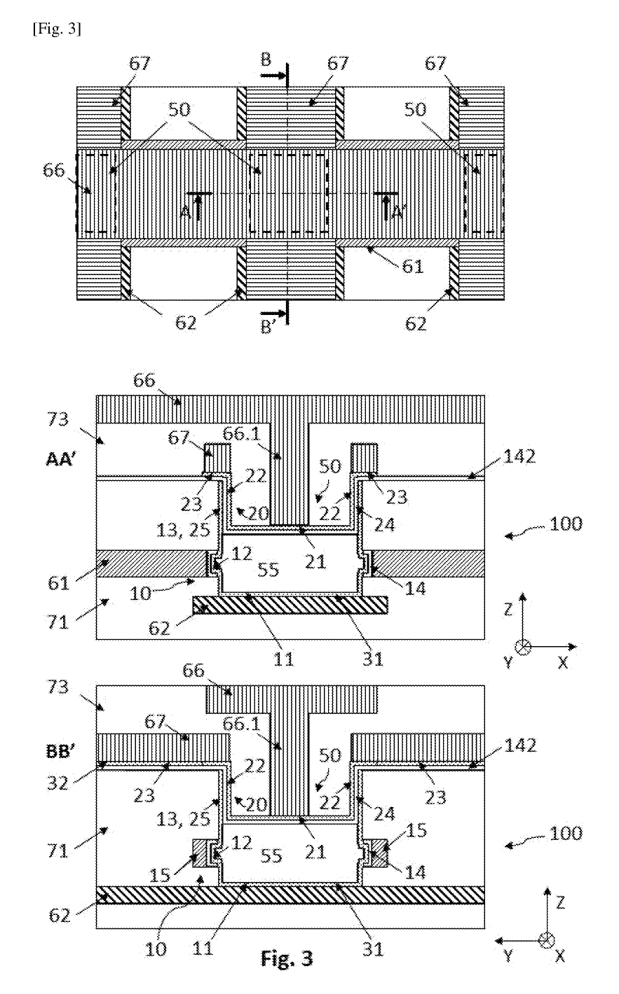

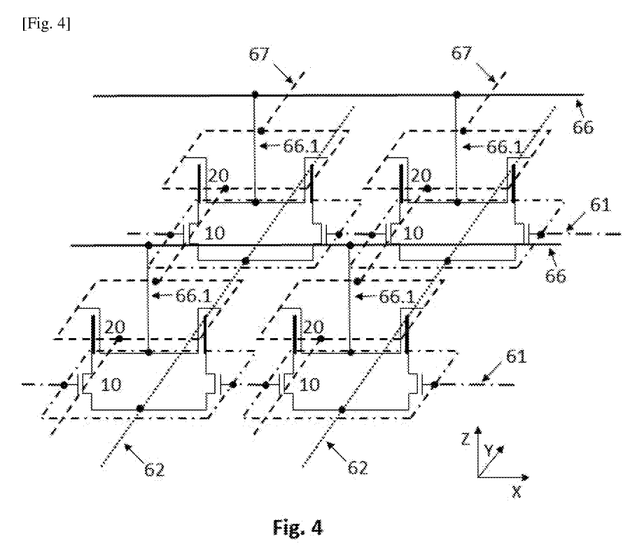

A second embodiment of stacking interconnections 100 according to the invention will now be described, with reference to FIG. 3 and 4. This embodiment can allow the surface area of the gate 25 of the read transistor 20 to be increased and/or the length of the channel 22 thereof to be better controlled. Only those differences with the first embodiment are explicitly described. The views and representation adopted are similar to those of FIG. 1 and 2. In the absence of additional information, the examples of ranges given for the dimensions of identical or similar elements are applicable to both embodiments. The same applies to the nature of the materials cited.

In this second embodiment, the first electrical contact area entirely surrounds the cavity when viewed from above. The read bit line 67 comprises a through-opening facing the cavity 50. The through-opening in this case is centered on the cavity 50 when viewed from above. The respective horizontal cross-sections of the through-opening and of the cavity can be to scale relative to one another, or even identical, which is the case here.

The read word line 66 is electrically connected to the source 21 of the read transistor 20 by a central via 66.1 passing through the through-opening of the read bit line 67. The write bit line 62 extends under the cavity 50 and defines the bottom thereof.

The memory cell comprises a separation volume 55 made of a dielectric material. The separation volume 55 occupies a lower part of the cavity 50, in contact with the bottom thereof via the first conformal active portion 31. At the bottom, the first conformal active portion 31 is in contact with the write bit line 62 and the separation volume 55 on two opposite sides thereof. The source 11 of the write transistor 10 extends into a lower part of the first conformal active portion 31 surrounding the cavity 50 on its sidewall, and can extend to the bottom thereof. It is electrically connected to the write bit line 62.

The separation volume 55 partially fills the cavity from the bottom thereof, until it reaches a level higher than that defined by the channel 12 of the write transistor 10. It completely covers the channel 12. The channel 12 is thus in contact with the gate dielectric 14 of the write transistor 10 and the separation volume 55 on two opposite faces thereof. As will become apparent upon reading the description, and as shown in FIG. 2, the separation volume 55 defines a distance along the Z-axis, between the channel 12 of the write transistor 10 and the gate 25. It further defines a length of the channel 22 of the read transistor 20.

The second conformal dielectric layer 142 is in contact with the first conformal active portion 31 at the sidewall of the cavity 50 on the perimeter of an upper part of the cavity 50. This physical contact area defines the gate dielectric 24 of the read transistor 20. The second conformal dielectric layer 142 extends over the separation volume 55, so as to be in contact therewith. Inside the cavity, it has a cuvette shape that conforms to the shape of the boundaries of a volume of the cavity remaining free by the separation volume 55 and the first conformal active portion 31.

The inner part of the second conformal active portion 32 extends over the second conformal dielectric layer 142, so as to be in contact therewith. It has a cuvette shape that conforms to the shape of the sidewall of the cavity 50, in the direction in which it is in contact with the sidewall via the second conformal dielectric layer 142 and the first conformal active portion 31. The region thus in contact with the sidewall of the cavity 50 defines the channel 22 of the read transistor 20. The channel 22 has a shape of a ribbon wound about itself along the sidewall of the cavity 50, the length whereof, parallel to the Z-axis, is defined by the distance separating the upper face of the lower dielectric stack 71 from the upper face of the separation volume 55. The gate 25 of the read transistor 20 is defined by the region of the first conformal active portion 31 facing the channel 22. It is therefore electrically connected to the channel 12 of the write transistor 10 by the first conformal active portion 31.

The inner part of the second conformal active portion 32 fully covers the separation volume 55, such that it is in contact therewith via the second conformal dielectric layer 142. The inner part defines, with the bottom and the sidewall of the cavity 50, a closed volume occupied by the separation volume 55. The central via 66.1 reaches the second conformal active portion 32 on an area facing the separation volume 55, defining the second electrical contact area. The latter can be centered on the cavity 50, as shown in FIG. 3.

The entire outer part is in contact with the upper face of the lower dielectric stack 71 via the second conformal dielectric layer 142. It forms a flange surrounding the inner cuvette-shaped part. It is substantially planar and horizontal so as to receive the read bit line 67.

An advantageous array arrangement of memory cells according to this second embodiment will be described with reference to FIG. 4. The same line pattern rules as in FIG. 2 has been used. Again, some electrical contacts are marked using solid disks. The gate 25 of the read transistor 20 is marked by a bold line. A symbol reminiscent of that conventionally used for a transistor of the FET type has been adopted for the write transistor 10.

Unlike in the first embodiment, the read transistor 20 occupies an upper part of the cavity 50 relative to the write transistor 10. The gate 25, the gate dielectric 24 and the channel 22 thereof wind around the cavity 50. As a consequence, the intrinsic capacitance of the gate 25 of the read transistor 20 can have an increased storage capacitance at equivalent memory cell density, compared to that of the first embodiment. This makes it possible to increase the retention time, in particular when the basic information unit is stored in the form of electrical charges in the gate 25. The width of the channel 22, substantially equal to the length of the circumference of the cavity 50, can be increased, which can have certain advantages, such as faster reading or a higher reading signal.

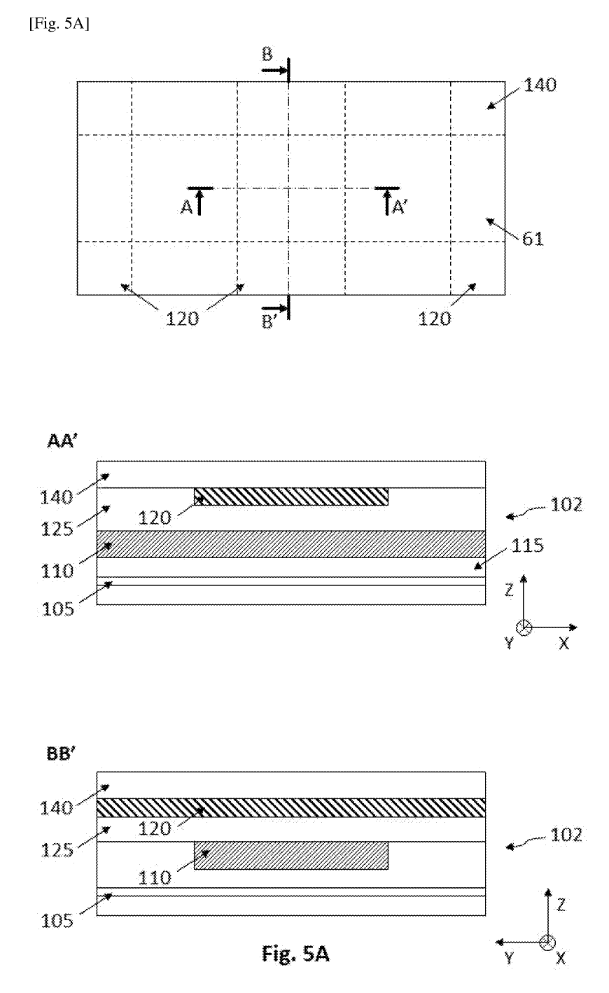

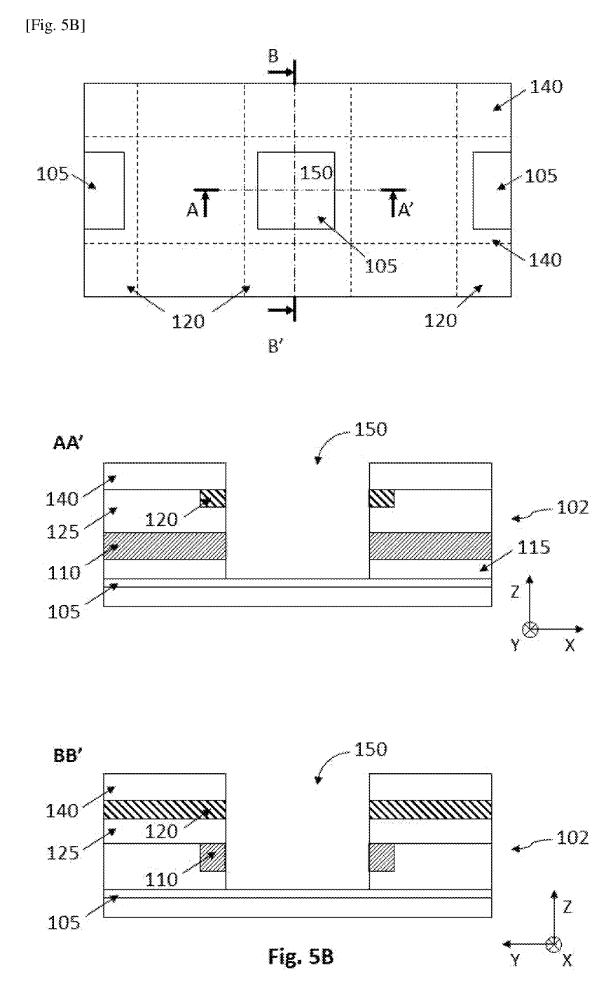

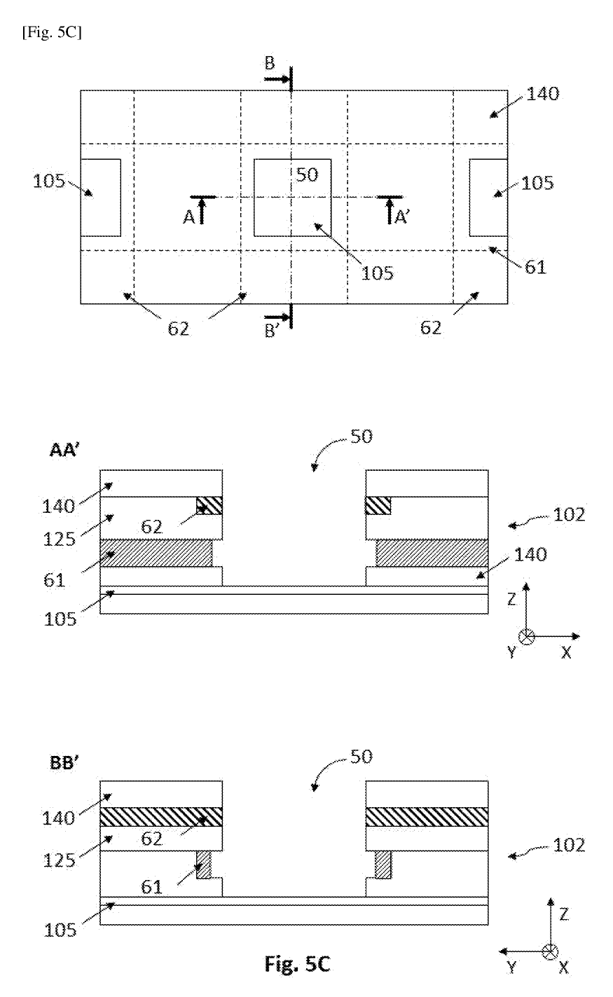

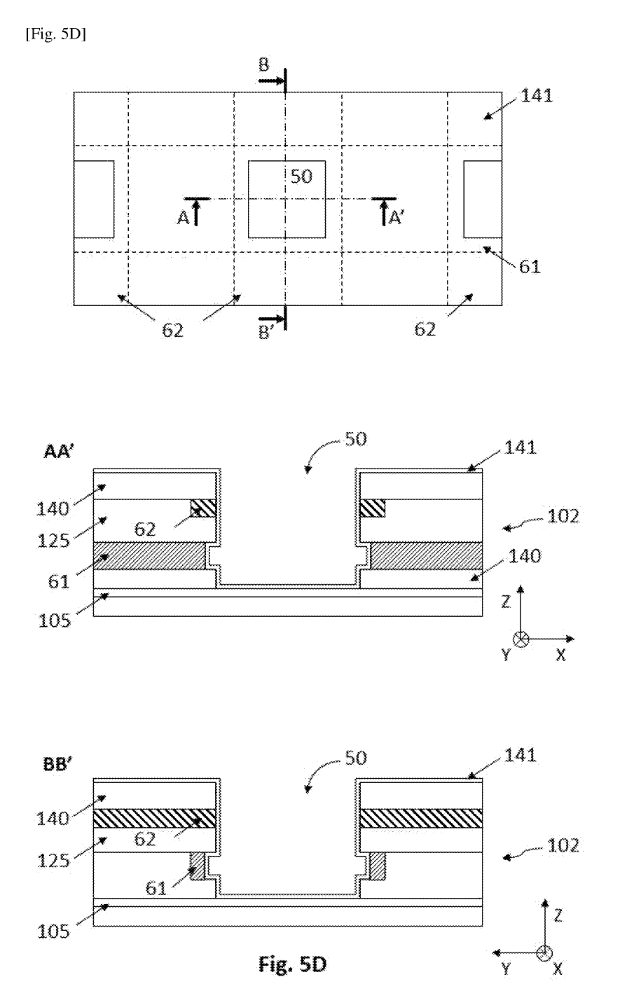

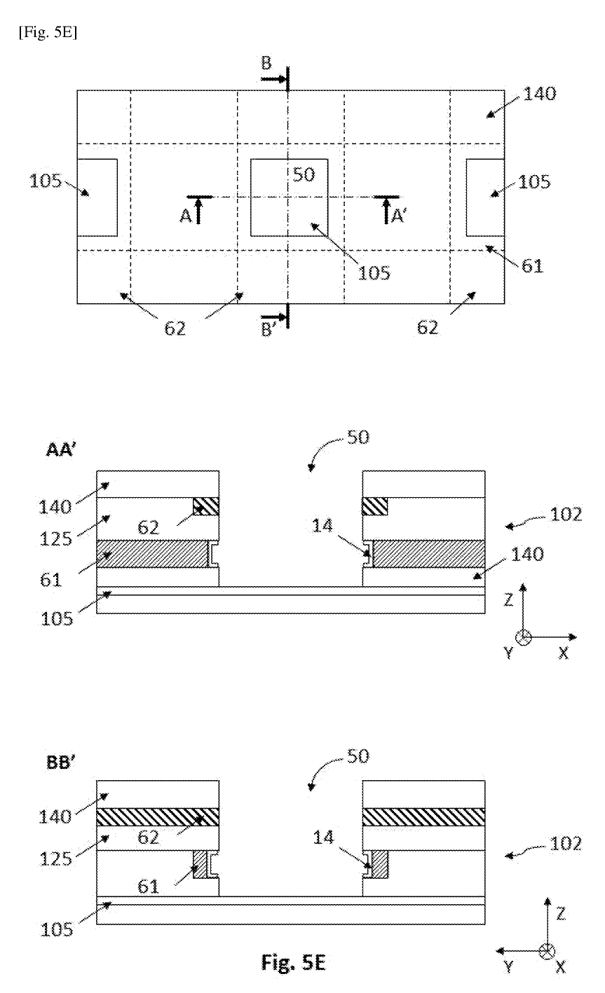

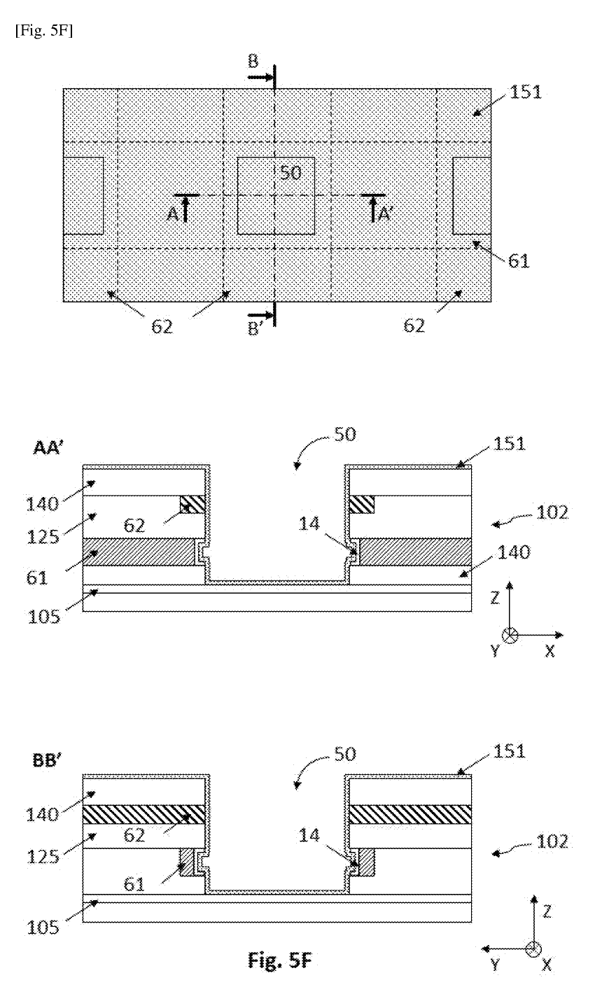

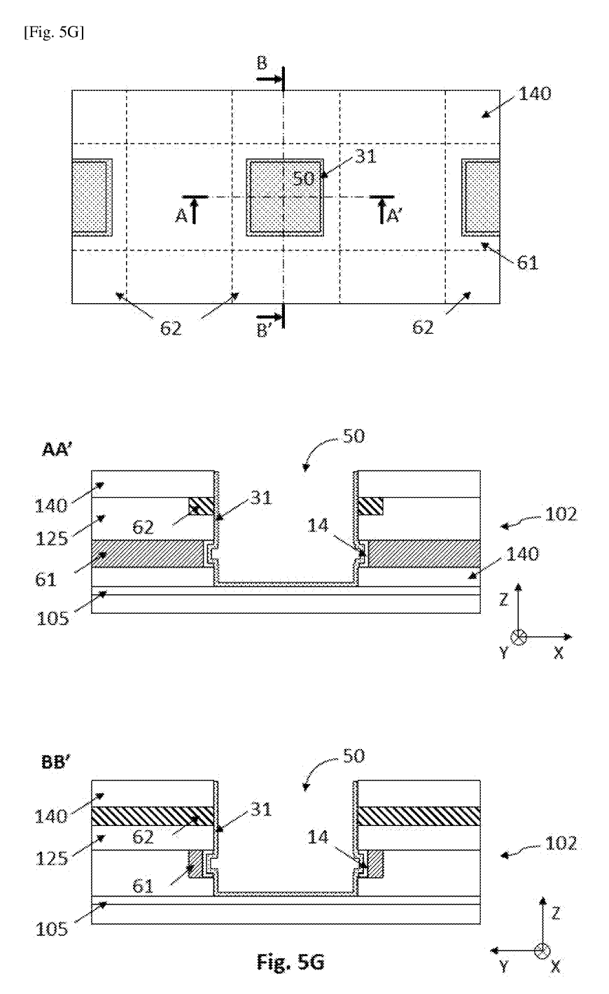

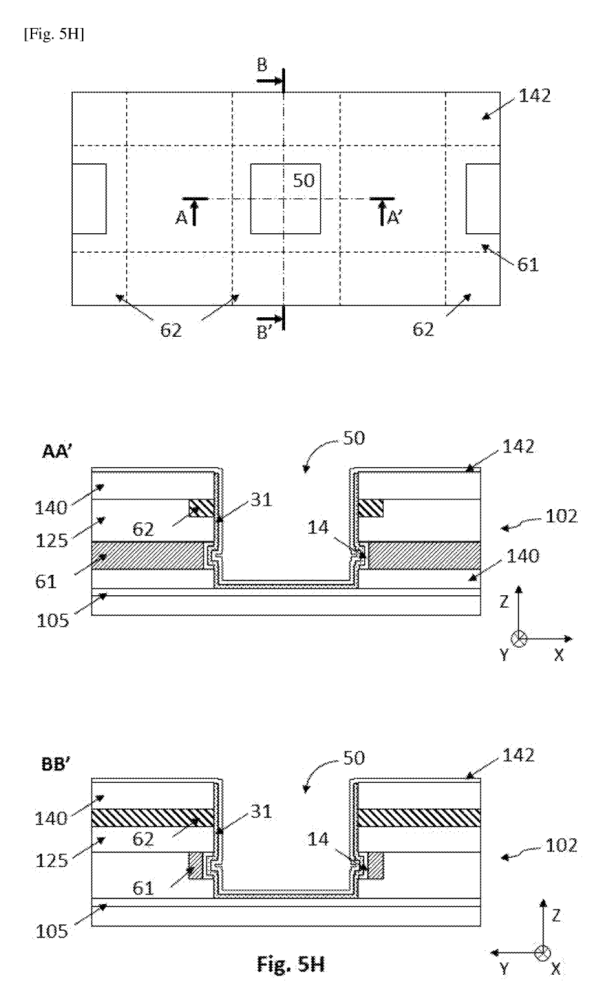

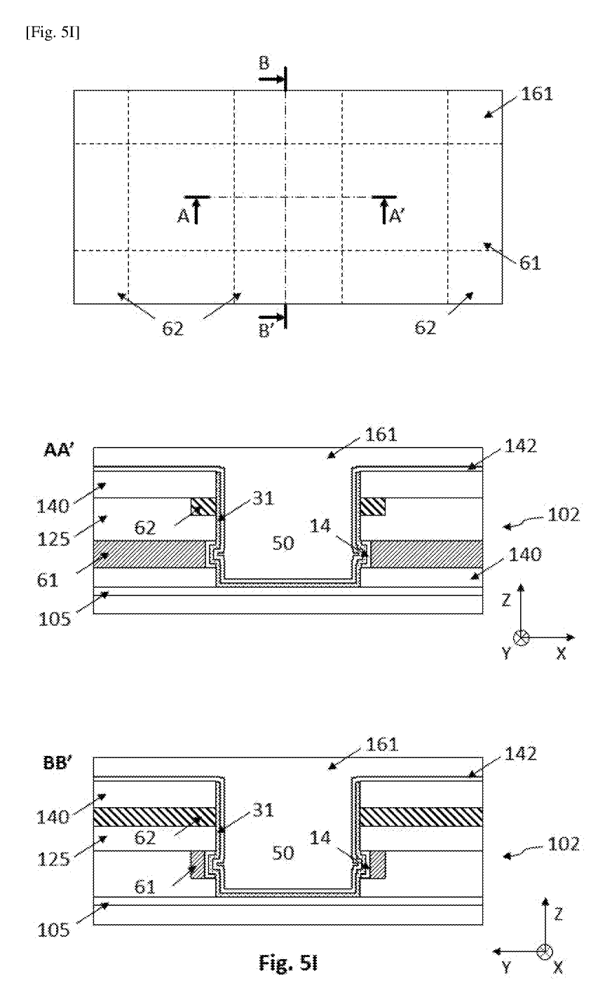

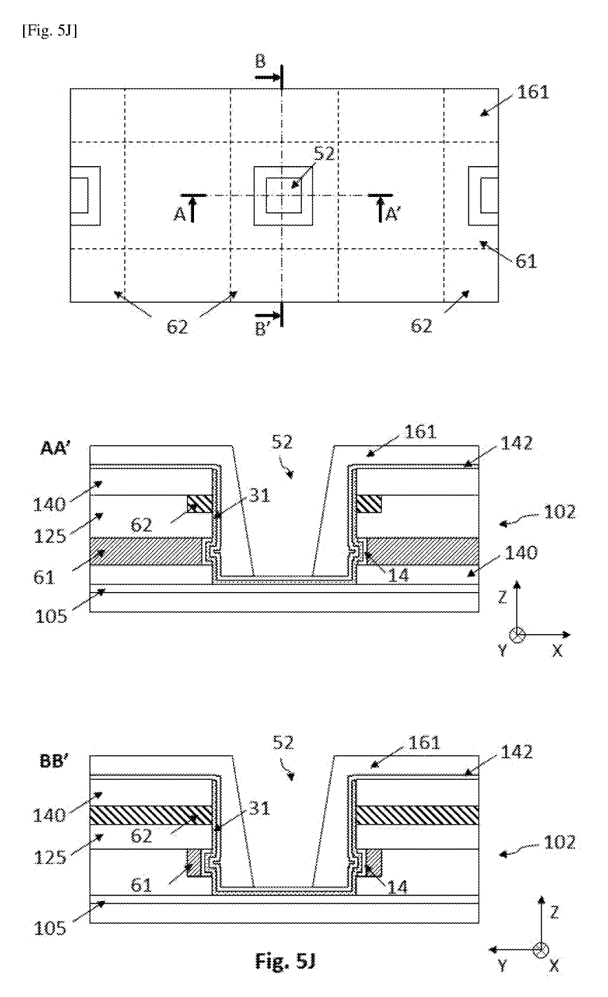

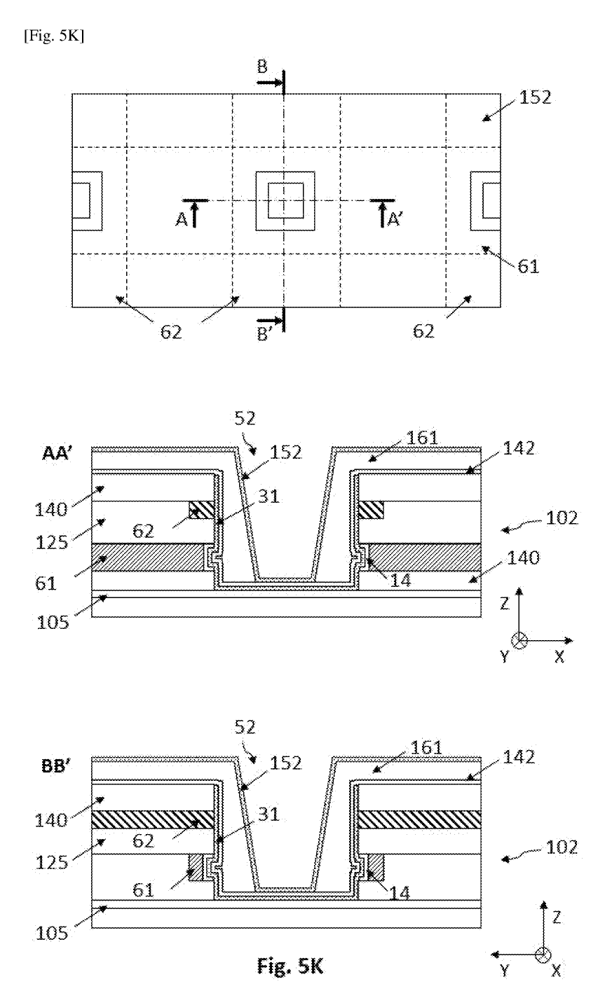

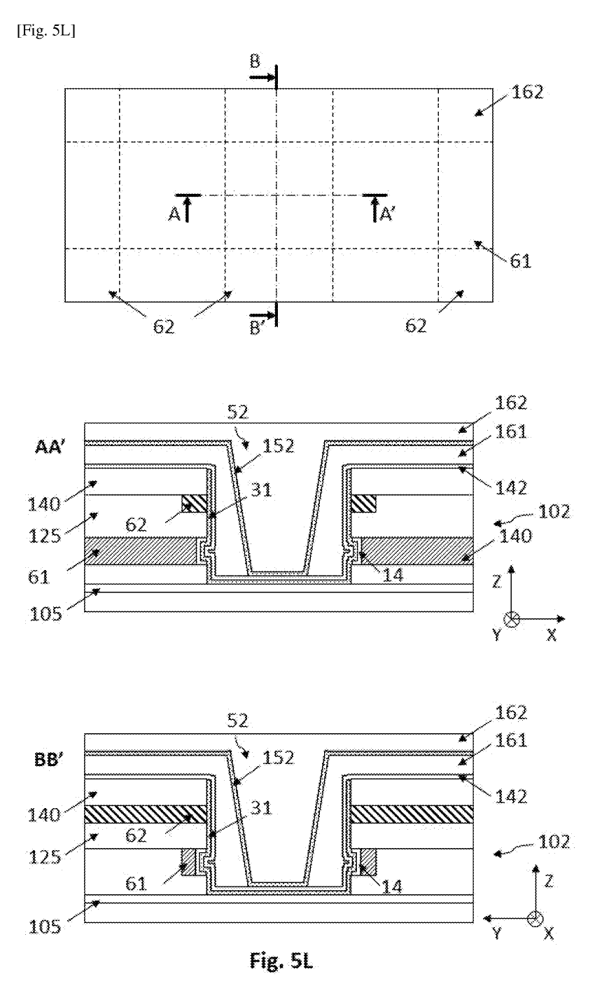

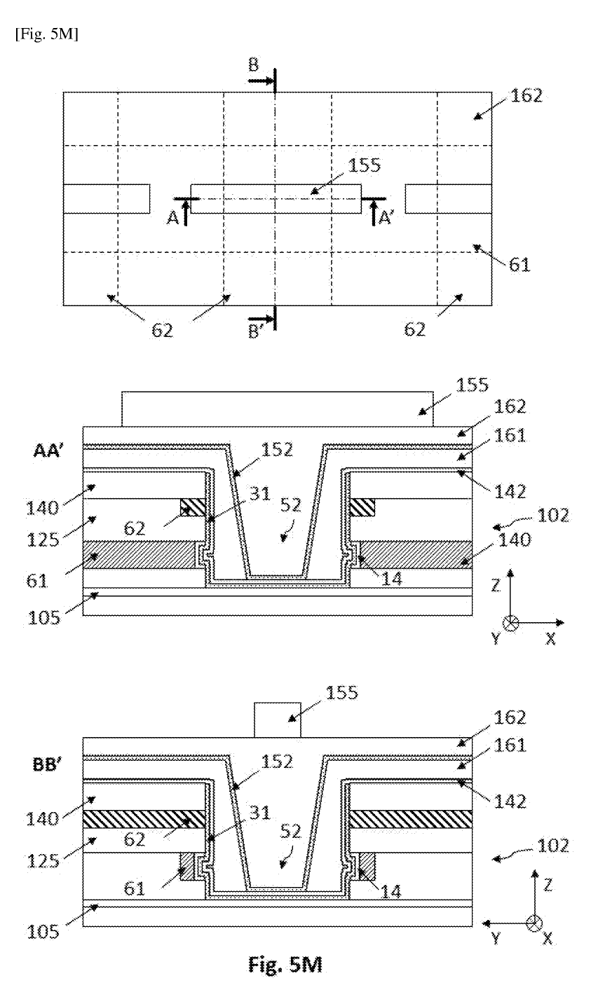

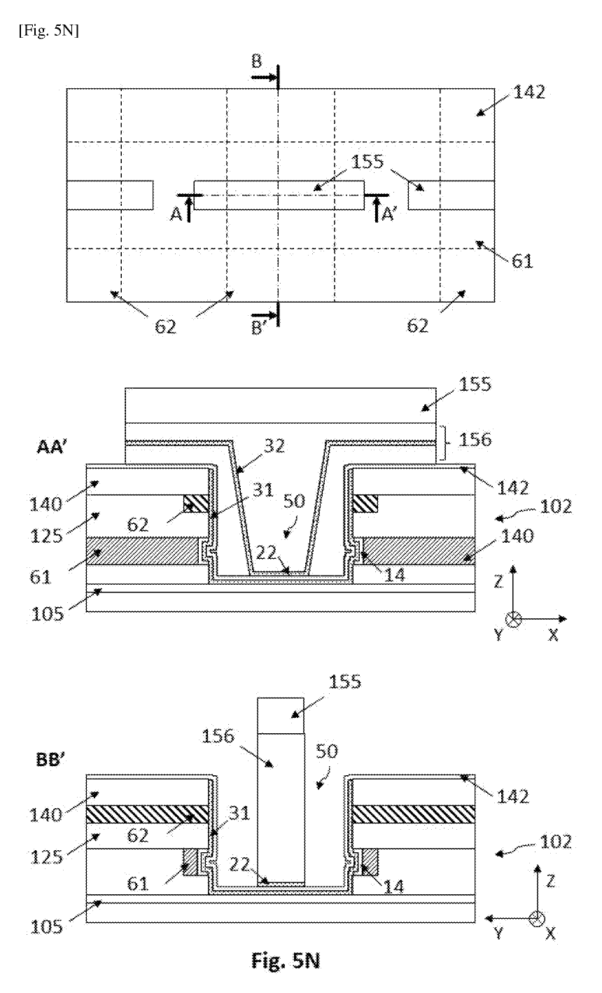

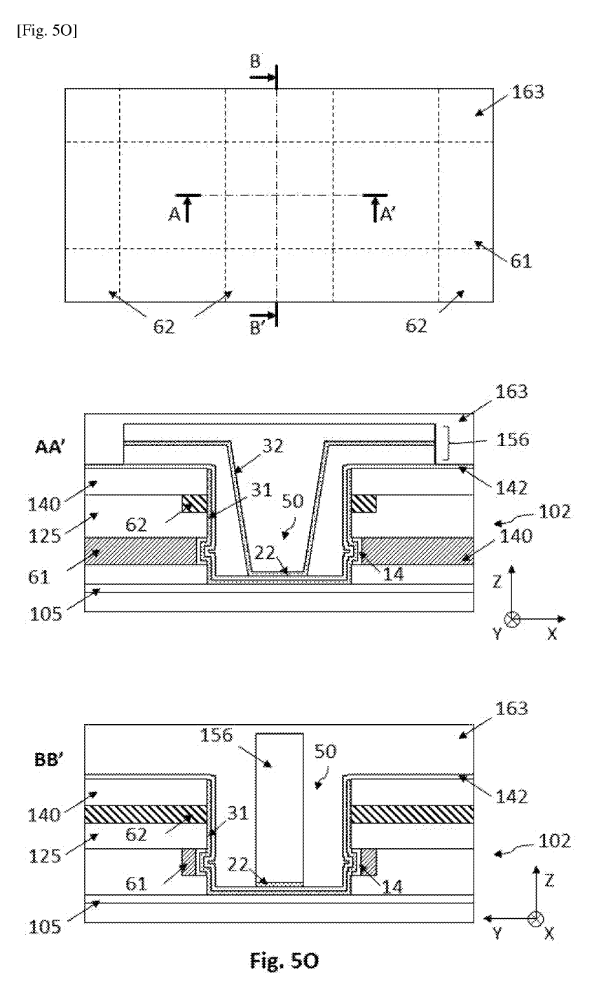

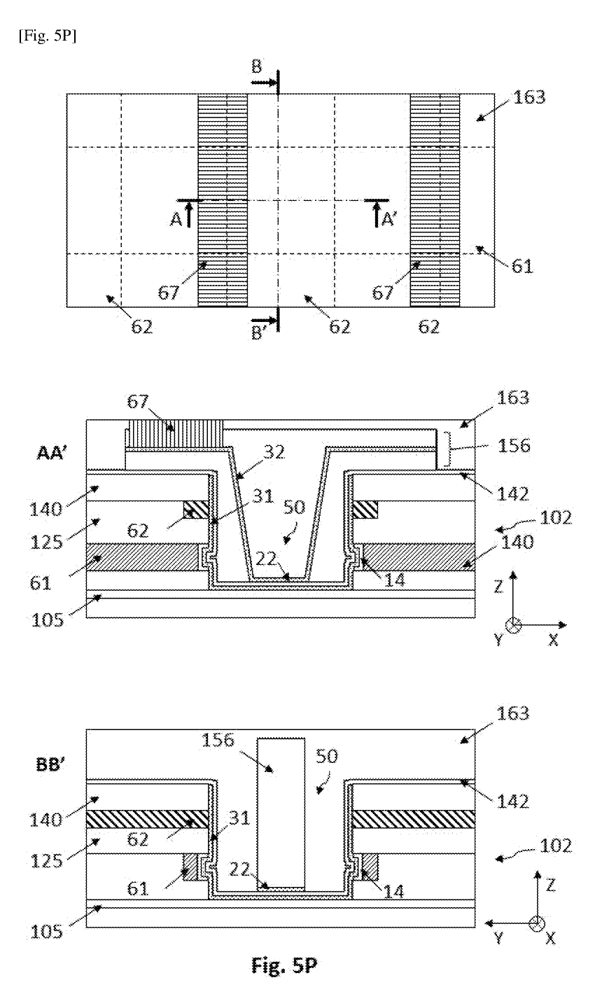

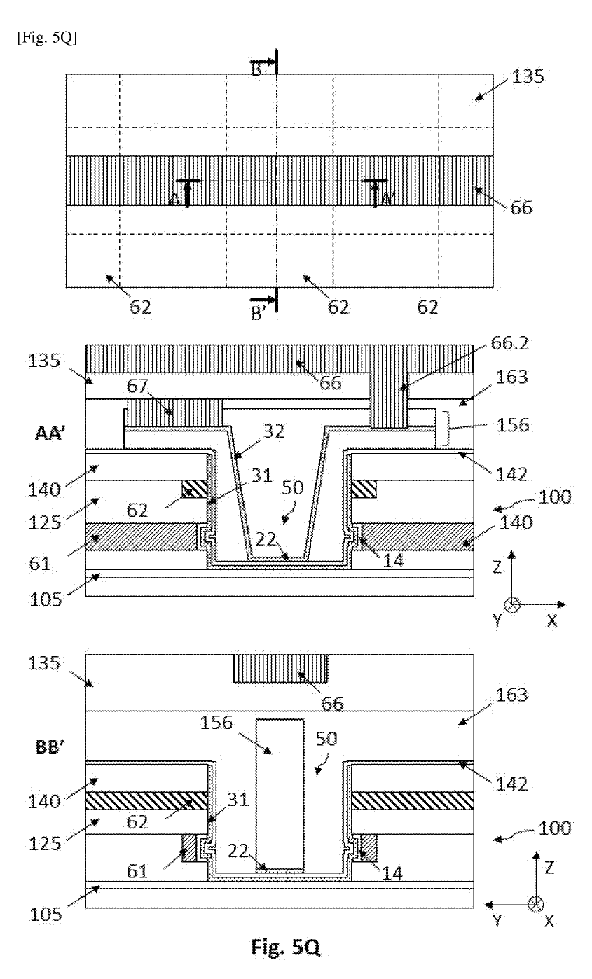

A first method for producing an interconnect stack 100 according to the first embodiment is now described, with reference to FIGS. 5A-5Q. As in FIG. 1 and 3, the top of each figure shows a top view, the middle shows a view along the cutting plane A-A’, and the bottom shows a view along the cutting plane B-B’. Cutting planes A-A' and B-B' are shown in the top view. Only the elements in the foreground are shown therein. However, to better identify the elements, write address lines are marked with dotted lines.

In FIG. 5A, an intermediate structure 102 is provided. The intermediate structure 102 comprises first interconnection levels of the interconnect stack 100, comprising a first conductive line 110 and a second conductive line 120. The intermediate structure 102 rests on an upper face of a substrate (not shown). It further comprises, successively in the direction +Z, a first interlayer dielectric 115, a second interlayer dielectric 125 and an upper dielectric layer 140. The second interlayer dielectric 125 is in contact with the first interlayer dielectric 115 and the upper dielectric layer 140. In this case, a direct orthonormal frame meeting the same definition as that established is used to describe the interconnect stacks 100 of FIG. 1 and 3.

The first and second conductive lines 110, 120 extend parallel to the upper face of the substrate and to the plane (X, Y), as do the first and second interlayer dielectrics 115, 125 and the upper dielectric layer 140. In this example, the first conductive line 110 extends along the X-axis in the first interlayer dielectric 115 and lies flush with an upper face thereof. The second conductive line 120 extends along the Y-axis in the second interlayer dielectric 125, and lies flush with an upper face thereof. The upper dielectric layer 140 is in contact with the second conductive line 120.

The first interlayer dielectric 115 comprises an etch stop sublayer 105 extending parallel to the plane (X, Y) at a dimension Z strictly less than that of the first conductive line 110. The etch stop sublayer 105 is therefore located at a distance from the first conductive line 110. For example, it is spaced from the first conductive line 110 by a distance between 10 nm and 50 nm, in the Z direction.

The etch stop sublayer 105 is made of a material that allows etching thereon to be selectively stopped when etching the first interlayer dielectric 115. For example, it is made of silicon nitride (SiN) or silicon carbonitride (SiCN). The remainder of the first interlayer dielectric 115 is made of one or more dielectric materials. It can be made of silicon oxide (SiOₓ), or of a material with a low dielectric constant, such as fluorine-doped silicon oxide (SiOF).

The second interlayer dielectric 125 and the upper dielectric layer 140 are made of one or more dielectric materials, for example SiOₓ or SiOCH. The first and second conductive lines 110, 120 can be made of the same examples of materials as those given for the write word line 61 and the write bit line 62 respectively of the first and second embodiments. They are made of different materials.

The first conductive line 110 can have a thickness measured parallel to the Z-axis, of between 10 nm and 50 nm, and a width measured parallel to the Y-axis of between 80 nm and 200 nm. The second conductive line 120 can have a thickness measured parallel to the Z-axis, of between 10 nm and 25 nm, a width measured parallel to the X-axis of between 80 nm and 200 nm. The first and second conductive lines 110, 120 can be separated by a distance of between 10 nm and 50 nm, along the Z-axis. The thickness of the upper dielectric layer 140 can be between 10 nm and 50 nm.

In FIG. 5B, an opening 150 is etched from an upper face of the upper dielectric layer 140 until reaching the etch stop sublayer 105. This operation can be carried out in one or more successive etching operations, the latter being selective with respect to the etch stop sublayer 105. The opening 150 advantageously has, as in this case, a sidewall substantially orthogonal to the plane (X, Y). Alternatively, it can be inclined at an angle of less than 10° or 20° to the Z-axis.

The opening 150 can have a horizontal cross-section of any shape, for example a rectangular or circular cross-section. In this case, it consists of four substantially planar, orthogonal walls, to within the corner rounding differences imposed by the manufacturing process. The opening 150 has a square horizontal cross-section, in this case having 100 nm sides. It crosses the first and second conductive lines 110, 120 from one end to the other. The latter open out into the opening 150 over the entire perimeter thereof.

In FIG. 5C, a lateral recess is etched in the first conductive line 110 through the opening 150, selectively with respect to the first and second interlayer dielectrics 115, 125, the upper dielectric layer 140 and the second conductive line 120. For this purpose, the first conductive line 110 is formed of one or more materials different to at least one material constituting the second conductive line 120, preferably to all the materials of the second conductive line 120. The first conductive line 110 is, in this case, made of titanium nitride (TiN). The second conductive line 120 is made of tungsten (W), ruthenium (Ru), molybdenum (Mo), or a combination thereof.

During this step, the first conductive line 110 is etched horizontally over a depth, for example of between 10 nm and 20 nm. Thus, at the end of step 5C, the cavity 50 with its notch at the recess of the first conductive line 110, and the write word and bit lines 61, 62 are obtained. The bottom of the cavity 50 is delimited by the etch stop sublayer 105.

In FIG. 5D, a first conformal dielectric layer 141 is conformally deposited on the upper face of the upper dielectric layer 140, and on the sidewall and bottom of the cavity 50. A part of this layer that conforms to the shape of the notch in the sidewall of the cavity 50 is intended to become the gate dielectric 14 of the write transistor 10. The first conformal dielectric layer 141 is preferably made of any dielectric material that can be etched selectively with respect to the upper dielectric layer 140 and to the etch stop sublayer 105, an etching of a few nanometers of the upper dielectric layer 140 and of the etch stop sublayer 105 being tolerable. It consists in this case of two sublayers made of HfO₂ and Al₂O₃ respectively.

In FIG. 5E, the first conformal dielectric layer 141 is etched over its entire thickness, anisotropically, in the direction -Z. A remaining part of the first conformal dielectric layer 141, protected by the notch in the cavity 50, and in contact with the write word line 61, constitutes the gate dielectric 14 of the write transistor 10.

This etching step makes it possible to free a contact edge of the write bit line 62 opening into the cavity 50, which is intended to electrically come into contact with the source 11 of the write transistor 10. The contact edge is obtained without damaging the gate dielectric 14 since it is protected during etching, by the notch, for example from ion bombardments. The gate dielectric 14 is thus of good quality.

In FIG. 5F, a first conformal semiconductor layer 151 is conformally deposited in contact with the upper face of the upper dielectric layer 140, the sidewall and the bottom of the cavity 50 and the gate dielectric 14 at the notch in the sidewall of the cavity 50. The first conformal semiconductor layer 151 conforms to the shape of a part of the notch that has remained free.

The first conformal semiconductor layer 151 is intended to receive the source 11, the channel 12, and the drain 13 of the write transistor 10, as well as the gate 25 of the read transistor 20.

The first conformal semiconductor layer 151 is made of any semiconductor material compatible with these functions. It can be made of indium-gallium-zinc oxide (IGZO), indium-zinc oxide (IZO), indium-tungsten oxide (IWO), indium-tin oxide (ITO), In₂O₃ or ZnO. It can also be made of a transition-metal dichalcogenide (TMD), such as MoS₂ or WSe₂ for example. It can also be made of an organic semiconductor. For example, it has a thickness between 1.5 nm and 10 nm.

In FIG. 5G, the part of the first conformal semiconductor layer 151 resting on the upper face of the upper dielectric layer 140 is removed, for example by a step of chemical mechanical polishing (CMP), optionally followed by cleaning. Where relevant, CMP stops on the upper face of the upper dielectric layer 140.

After or before removal, one or more optional steps can be carried out for implanting one or more parts of the first conformal semiconductor layer 151 intended to be an element of the write transistor 10, or of the read transistor 20, or an electrical connection between these elements. At the end of the step in FIG. 5G, the first conformal semiconductor layer 151 is removed everywhere, except for a part fully coating the sidewall and the bottom of the cavity, constituting the first conformal active portion 31.

In FIG. 5H, the second conformal dielectric layer 142 is deposited conformally.

In FIG. 5I, a first planarizing layer 161 is deposited in the cavity 50, and on the upper face of the upper dielectric layer 140, in contact with the second conformal dielectric layer 142. The first planarizing layer 161 has a substantially planar upper face parallel to the plane (X, Y) fully covering the second conformal dielectric layer 142. This upper face can optionally be obtained by a CMP step.

The first planarizing layer 161 is made of a dielectric material, for example with a low dielectric constant such as SiOF, or SiCO. It has a thickness measured along the Z-axis, at the cavity 50, that is greater than or equal to the depth of the cavity, for example at least greater than 10 nm. The larger this thickness, the better the electrical insulation between the first and second conformal active portions 31, 32. The first planarizing layer 161 can be flush with the upper face of the second conformal dielectric layer 142.

In FIG. 5J, a secondary cavity 52 is etched from the upper face of the first planarizing layer 161, extending into the cavity 50, to reach the second conformal dielectric layer 142 at the bottom of the cavity 50. The secondary cavity 52 crosses the first planarizing layer 161 from one end to the other. It is advantageously centered, along the X-axis, on the cavity 50. It can be a trench, which can optionally extend over a plurality of memory cells arranged on a same axis parallel to the Y-axis. Here it has a substantially square cross-section in any horizontal plane, with a side length that is strictly less than the length of the sides of the cavity 50.

The secondary cavity 52 is intended to serve as a support for the second conformal active portion 32. The length of its bottom along the X-axis defines the length of the channel 22 of the read transistor 20. When the width of its bottom along the Y-axis is strictly less than the width of the cavity 50 along this axis, it can define the width of the channel 22. According to the X-axis, at the write word line 61, the sidewall of the secondary cavity 52 is located at a sufficient distance from the first conformal active portion 31 for the operation of the write and read transistors 10, 20 to not be disturbed by one another. This distance is, for example, between 10 nm and 20 nm.

Advantageously, the secondary cavity 52 has a sidewall that is inclined relative to the Z-axis, for example by an angle between 0° and 25°, in this case by an angle of 15°. An inclined sidewall makes it possible to obtain good uniformity and good reproducibility of the thickness of the second conformal active portion 32, in particular at the slope breaks. This allows a controlled and uniform electrical current S/D to be obtained between all the memory cells when the interconnect stack 100 comprises a plurality thereof. This inclination also allows the first and second electrical contact areas on the inclined sidewall to be extended, thus improving the electrical connection of the read word and bit lines 66, 67 with the second conformal active portion 32.

In FIG. 5K, a second conformal semiconductor layer 152 is conformally deposited in contact with the first planarizing layer 161, including in the secondary cavity 52. This layer is intended to receive the source 21, the channel 22 and the drain 23 of the read transistor 20. It is made of any semiconductor material compatible with these functions.

The second conformal semiconductor layer 152 is, for example, made of polycrystalline silicon, indium-gallium-zinc oxide (IGZO), indium-zinc oxide (IZO), indium-tungsten oxide (IWO), indium-tin oxide (ITO), In₂O₃ or ZnO. It can also be made of a transition-metal dichalcogenide (TMD), such as MoS₂ or WSe₂ for example. It can also be made of an organic semiconductor. It can have a thickness between 1 nm and 20 nm.

In FIG. 5L, a second planarizing layer 162 is deposited in contact with the second conformal semiconductor layer 152, including in the secondary cavity 52. The second planarizing layer 162 has an upper face that is substantially planar and parallel to the plane (X, Y), fully covering the second conformal semiconductor layer 152. This upper face can optionally be obtained by a CMP step.

The second planarizing layer 162 is made of a dielectric material, for example silicon oxide SiOₓ. It has a thickness measured along the Z-axis, at the secondary cavity 52, that is greater than the depth thereof, for example at least greater by more than 10 nm. The second planarizing layer 162 can be flush with the upper face of the second conformal semiconductor layer 152.

In FIG. 5M, a pad 155 is produced in contact with the upper face of the second planarizing layer 162. It is intended to serve as a mask during an etching of a residual edge 156 shown in FIG. 5N.

The pad 155 is, in this case, centered on the cavity 50. It extends parallel to the X-axis over a length strictly greater than the width of the cavity 50 along this axis. The pad 155 has a width, parallel to the Y-axis, strictly less than the width of the secondary cavity 52 measured at the bottom thereof and minus twice the thickness of the second conformal semiconductor layer 152. Thus, it defines the width of the channel 22 of the read transistor 20. In any event, the pad 155 has a width strictly less than the width of the cavity 50 measured at the bottom thereof, parallel to the Y-axis.

The pad 155 is made of any material capable of resisting etching of the first and second planarizing layers 161, 162 and the second conformal semiconductor layer 152. It can be obtained by a photolithography step, optionally implementing a hard mask.

The step in FIG. 5N makes it possible to delimit the source 21, the channel 22, the drain 23 of the read transistor 20 and the electrical contact areas of the second conformal active portion 32 for the read word and bit lines 66, 67. The first and second planarizing layers 161, 162 and the second conformal semiconductor layer 152 are etched locally. Remaining parts of these layers, protected by the pad 155, together form a residual edge 156. The residual edge 156 comprises the second conformal active portion 32, sandwiched between the remaining parts of the first and second planarizing layers 161, 162.

The residual edge 156 passes all the way through the cavity 50 coated with the first conformal active portion 31 and the second conformal dielectric layer 142, in a direction parallel to the X-axis. It extends on either side of the cavity 50 along this axis, above the upper face of the upper dielectric layer 140. It has opposite sidewalls that are substantially planar and parallel to the plane (X, Z). These are located at a distance from the parts of the second conformal dielectric layer 142 lining the walls of the cavity 50 parallel to the plane (X, Z). Thus, the second conformal active portion 32 is in contact with the second conformal dielectric layer 142 only at the bottom of the cavity 50 over an area defining the channel 22 of the read transistor 20. The outer part of the second conformal active portion 32 is separated from the second conformal dielectric layer 142 by the first planarizing layer 161.

The width of the channel 22 of the read transistor 20 is defined by the width of the pad 155 along the Y-axis. In this case, the width of the pad 155 is strictly less than the width of the bottom of the secondary cavity 52.

In FIG. 5O, the pad 155 is removed. A third planarizing layer 163 is then deposited in contact with the second conformal dielectric layer 142, the residual edge 156, including in the cavity 50 between each face of the residual edge 156 parallel to the plane (X, Z) and the sidewall of the cavity 50. The residual edge 156 and the third planarizing layer 163 together fill the cavity 50 entirely.

The third planarizing layer 163 has a substantially planar upper face parallel to the plane (X, Y), optionally obtained by a CMP step. Its upper face covers the second conformal dielectric layer 142 facing the upper face of the upper dielectric layer 140. It can cover the residual edge 156, as shown here. It is located at a Z dimension strictly higher than those of respective parts of the second conformal active portion 32 intended to be contact areas for the read word and bit lines 66, 67 of the second conformal active portion 32. Thus, these contact areas are protected by the third planarizing layer 163. If obtained by CMP, the chemical-mechanical polishing step can cut into the residual edge 156 at the remaining part of the second planarizing layer 162, such that the third planarizing layer 163 is flush with the residual edge 156 at its upper face.

The third planarizing layer 163 is made of a dielectric material, for example silicon oxide.

In FIG. 5P, the read bit line 67 is brought into contact with the outer part of the second conformal active portion 32. Advantageously, the read bit line 67 protrudes into the cavity 50 in contact with the inner part of the second conformal active portion 32, at the sidewall of the cavity 50, and for example as far as the bottom of the cavity 50. The read bit line 67 can be formed by a single or dual damascene process. In this case, a trench extending parallel to the Y-axis, intended to receive the read bit line 67, is etched locally from the upper face of the third planarizing layer 163, to reach the second conformal active portion 32, through the second planarizing layer 162. The trench is then filled with metal, optionally after having coated it with one or more diffusion barrier and/or bonding layers. Filling can involve one or more CMP and cleaning steps.

In FIG. 5Q, the read word line 66 is brought into contact with the outer part of the second conformal active portion 32. Advantageously, the read word line 66 can comprise a part in electrical contact with the lateral via 66.2 and protruding into the cavity 50. Said part of the read word line 66 being in contact with the inner part of the second conformal active portion 32, at the sidewall of the cavity 50, and for example as far as the bottom of the cavity 50. The read word line 66 and the lateral via 66.2 can be formed by a dual damascene process. In this case, a third interlayer dielectric 135 is deposited on the third planarizing layer 163 and the read bit line 67, in contact therewith. A trench extending parallel to the X-axis is then etched locally and is intended to receive the read word line 66 and the lateral via 66.2. The trench is then filled with metal, optionally after having coated it with one or more diffusion barrier and/or bonding layers. Filling can involve one or more CMP and cleaning steps.

At the end of FIG. 5Q, an interconnect stack 100 comprising a memory cell according to the first embodiment is obtained.

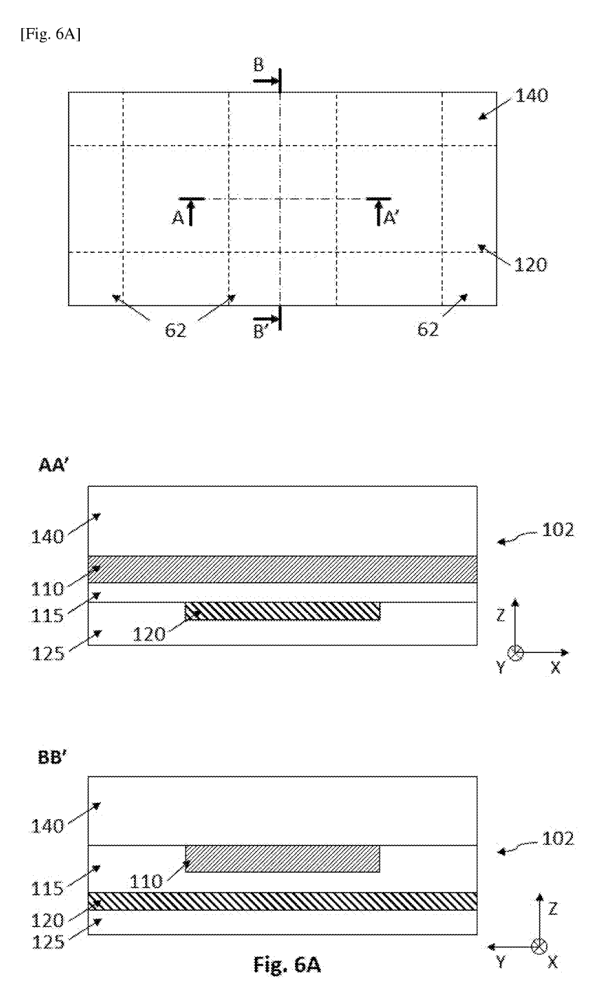

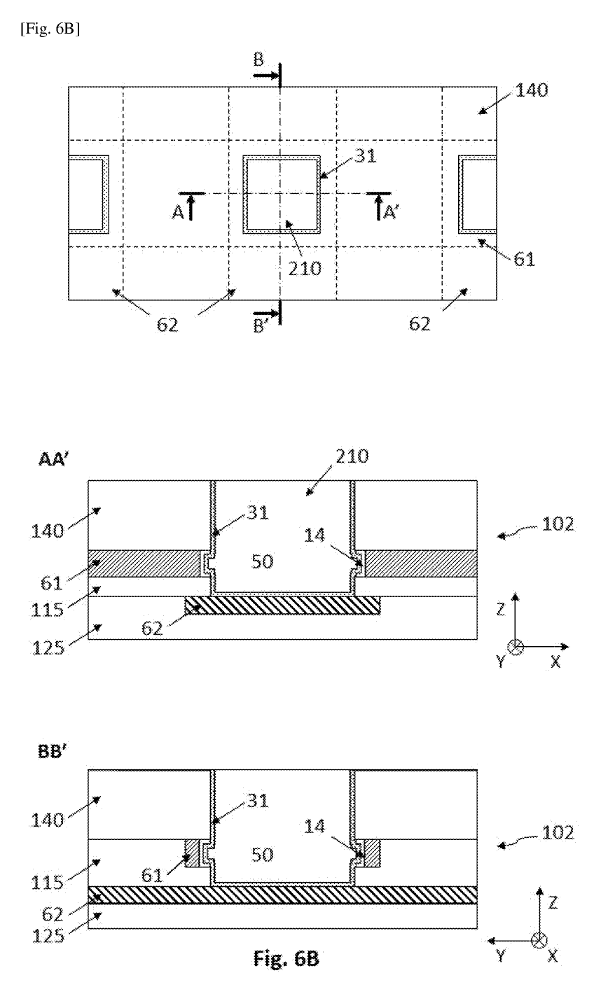

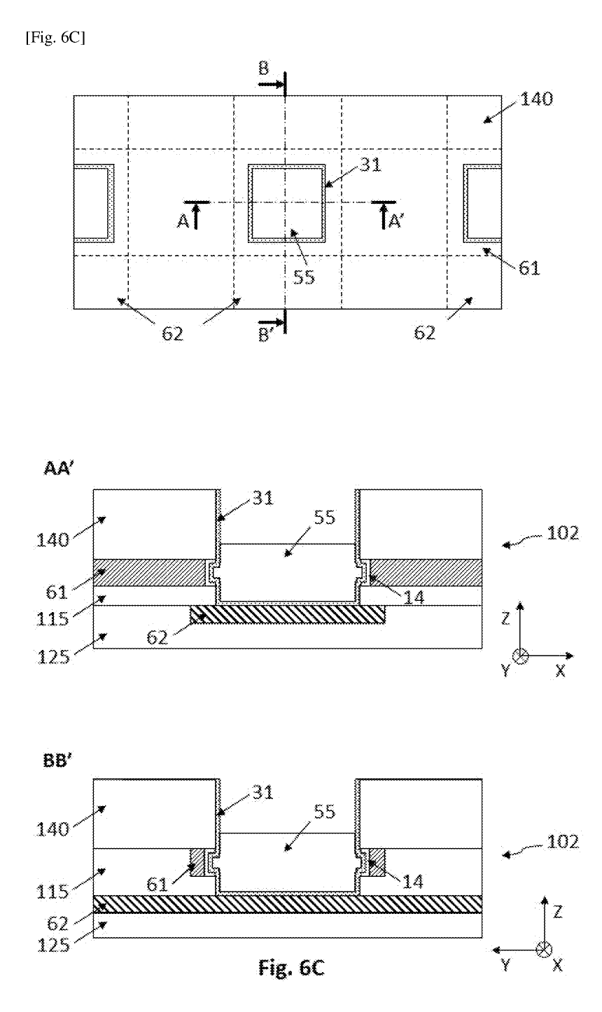

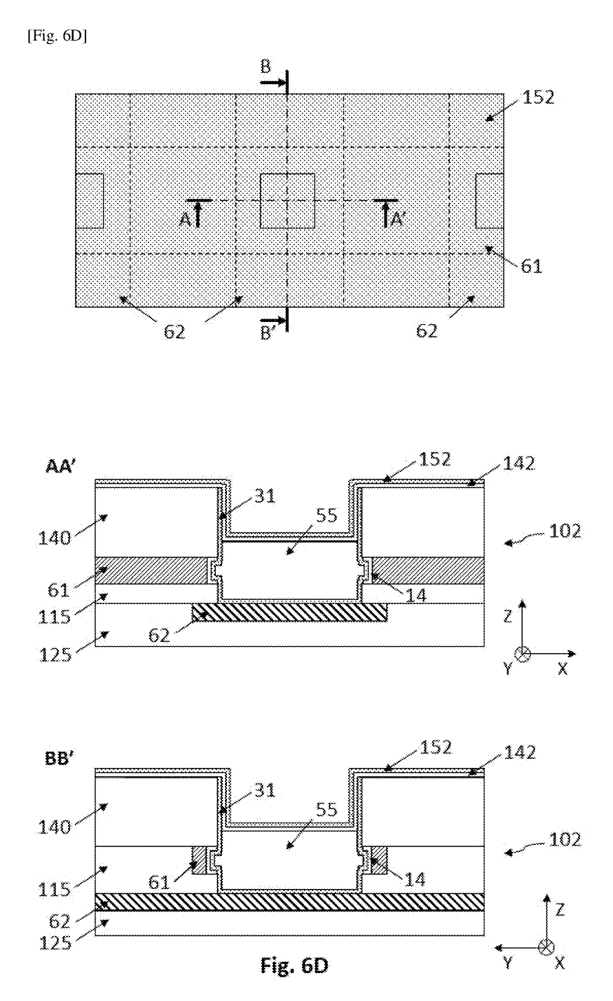

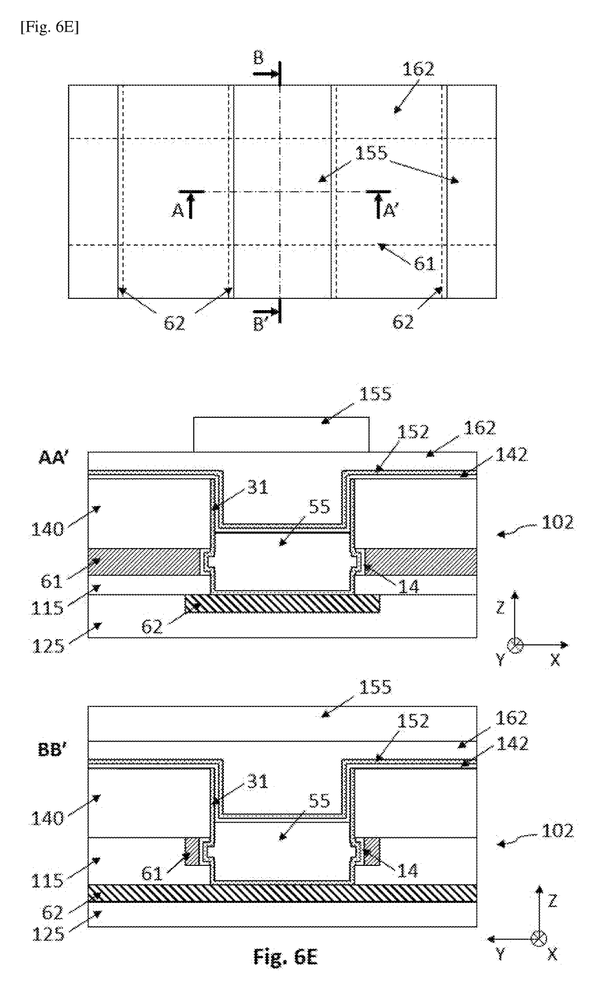

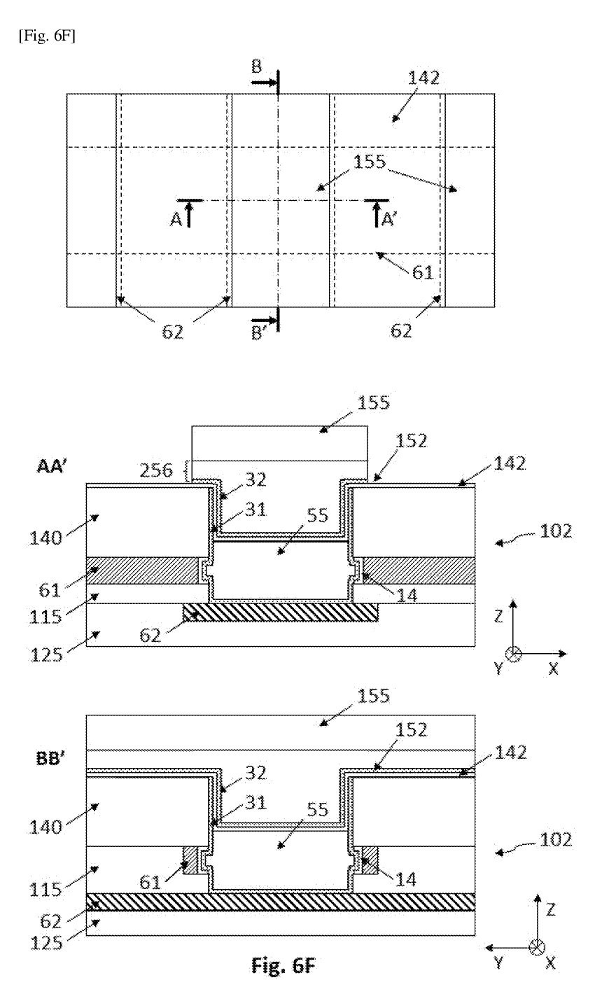

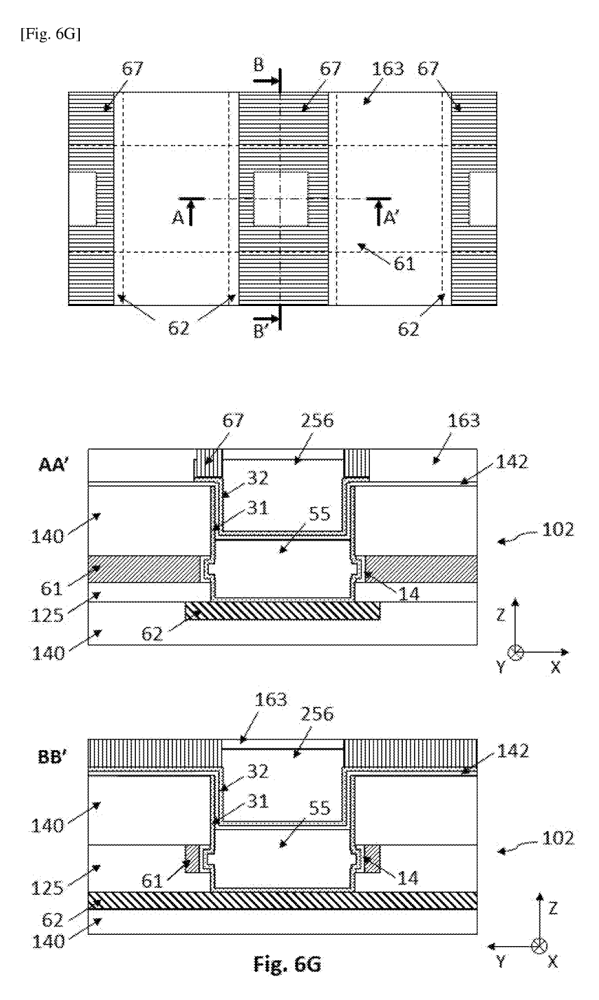

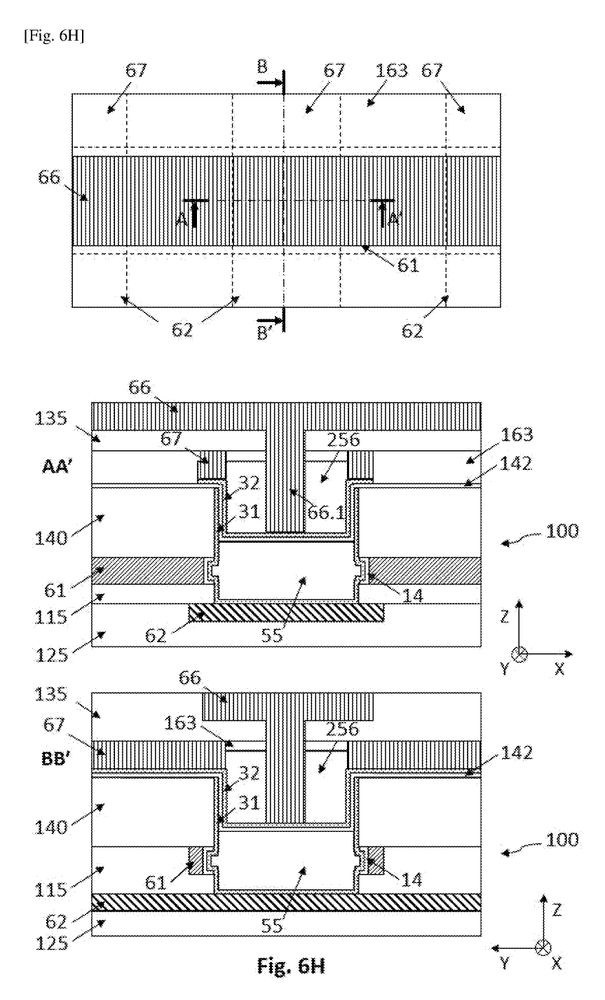

A second method for producing an interconnect stack 100 according to the second embodiment will now be described, with reference to FIG. 6A=6H. Only the differences with the first manufacturing method are explicitly described. The steps of the method are shown in a similar manner to that adopted for FIGS. 5A-5Q.

FIG. 6A provides the intermediate structure 102 in which the order of the first and second interlayer dielectrics 115, 125 has been reversed. Thus, successively, in the increasing Z direction, the second interlayer dielectric 125, then the first interlayer dielectric 115 in contact with the second interlayer dielectric 125 are shown. The upper dielectric layer 140 extends in contact with the first interlayer dielectric 115 and the first conductive line 110.

Advantageously, as is the case here, the first interlayer dielectric 115 does not comprise an etch stop layer. The upper dielectric layer 140 has, for example, a thickness of between 20 nm and 100 nm. The first conductive line 110 is separated from the second conductive line 120 by a distance along the Z-axis, for example a distance of between 10 nm and 50 nm, in the Z direction.

The steps of FIGS. 5B-5G of the first manufacturing method are then carried out, for which the second conductive line 120 plays the role of an etch stop of the etch stop sublayer 105 when producing the opening 150.

In FIG. 6B, the cavity 50 is filled with a filler material 210. For this purpose, a filler layer made of the same material as that of the filler material 210 protruding from the cavity 50 can be deposited. A chemical-mechanical polishing operation is then carried out, stopping on the upper dielectric layer 140. The chemical-mechanical polishing operation can be that of FIG. 5G.

At the end of FIG. 6B, the filler material 210 at least partially fills the cavity 50, so as to cover the channel 12 of the write transistor 10. Preferably, it fills the entire cavity 50, as shown here. In this figure, the filler material 210 lies flush with the top face of the upper dielectric layer 140.

The filler material 210 is made of one or more dielectric materials. Here it is made of silicon oxide.

In FIG. 6C, the filler material 210 is partially etched to retain only a separation volume 55 filling a lower part of the cavity 50, facing the channel 12 of the write transistor 10. The filler material 210 is, for example, etched over a depth of between 20 nm and 100 nm. The resulting separation volume 55 has, for example, a height measured parallel to Z of between 30 nm and 100 nm.

The first conformal active portion 31 has a revealed part extending, at the sidewall of the cavity 50, into a free volume thereof. The free volume is complementary to the separation volume 55. This revealed part is intended to define the respective lengths, along the Z axis, of the gate 25 and of the channel 22 of the read transistor 20. The height of the separation volume 55 is intended to define the distance between the channel 12 of the write transistor 10 and the gate 25 of the read transistor 20.

After etching, an optional step can be carried out for implanting the first conformal active portion 31, protected by the separation volume 55. It is thus possible to reduce the electrical resistance between the channel 12 of the write transistor 10 and the gate 25 of the read transistor 20. Where relevant, the implanted species are preferably of the donor type.

In FIG. 6D, the second conformal dielectric layer 142, which, in this second manufacturing method, is in contact with the separation volume 55, is deposited conformally. It coats the part of the first conformal active portion 31 that was exposed during the etching of FIG. 6C. The region of the second conformal dielectric layer 142 in contact with the first conformal active portion 31 is intended to be the gate dielectric 24 of the read transistor 20.

The second conformal semiconductor layer 152 is then conformally deposited in contact with the second conformal dielectric layer 142.

In FIG. 6E, the second planarizing layer 162 is deposited in contact with the second conformal semiconductor layer 152, and therefore in the free volume of the cavity 50. The pad 155 is then formed. The pad 155 fully covers the cavity 50. When the interconnect stack 100 comprises a plurality of memory cells arranged in an array, the pad 155 can extend over a plurality of contiguous memory cells, so as to cover the cavities thereof. In this case, it is centered on the cavity 50 along the X-axis. The dimension thereof along this axis is strictly greater than that of the cavity 50. For example, it has a dimension along the X-axis that is 20 nm greater than that of the cavity 50.

In FIG. 6F, the regions of the second planarizing layer 162 and of the second conformal semiconductor layer 152 that are not covered by the pad 155, are etched over the entire thickness thereof. This operation makes it possible to delimit the outer part of the second conformal active portion 32. Etching stops on the second conformal dielectric layer 142, facing the upper face of the upper dielectric layer 140. Remaining parts of the second planarizing layer 162 and of the second conformal semiconductor layer 152, which were protected by the pad 155, together constitute a residual pad 256 resting in the cavity 50 on the separation volume 55. The residual pad 256 completely fills the free volume of the cavity 50 coated with the second conformal dielectric layer 142 and with the second conformal active portion 32. It rests on the second conformal dielectric layer 142 on a region surrounding the cavity 50, facing the upper face of the upper dielectric layer 140.

In FIG. 6G, the read bit line 67 is formed, in contact with the first electrical contact area of the outer part of the second conformal active portion 32. The read bit line 67 can be formed by a single or dual damascene process.

Here, the third planarizing layer 163 on the residual pad 256 and the second conformal dielectric layer 142 are deposited. Then, a trench extending parallel to the Y-axis, intended to receive the read bit line 67, is etched locally from the upper face of the third planarizing layer 163, to reach the second conformal active portion 32, through the second planarizing layer 162. The trench preferably has an external width along the X-axis that is strictly less than the width of the residual pad 256 in this direction. It is here centered on the residual pad 256 and the cavity 50 along the X-axis. It surrounds the cavity 50 when viewed from above. It does not cover the cavity 50 in this view.

The trench is then filled with metal, optionally after having coated it with one or more diffusion barrier and/or bonding layers. Filling can involve one or more CMP and cleaning steps.

In FIG. 6H, the read word line 66 and a central via 66.1 are formed according to a method similar to that of 5Q, replacing the lateral via 66.2 with the central via 66.1. At the end of FIG. 6H, an interconnect stack 100 comprising a memory cell according to the second embodiment is obtained.

Specific embodiments have just been described. Various alternatives and modifications will become apparent to a person skilled in the art.

1. An interconnect stack extending along a main plane thereof, and comprising at least one memory cell of the 2T0C type, each memory cell comprising:
o a cavity in the interconnect stack,
o a first conformal active portion made of a semiconductor material coating a sidewall and a bottom of the cavity, the bottom extending parallel to the main plane,
o a read transistor and a write transistor, respectively comprising a gate and a channel arranged in the cavity, wherein the channel of the write transistor and the gate of the read transistor are formed in two separate regions of the first conformal active portion and electrically connected by the first conformal active portion.

2. The interconnect stack according to claim 1, wherein the channel of the write transistor extends continuously over the sidewall of the cavity so as to form a ribbon wound about itself.

3. The interconnect stack according to claim 2, further comprising a write word line extending parallel to the main plane of the interconnect stack, wherein a gate of the write transistor is formed in a region of the write word line surrounding the cavity.

4. The interconnect stack according to claim 1, further comprising a first read address line extending parallel to the main plane, wherein the memory cell comprises a second conformal active portion made of a semiconductor material divided into an inner part and an outer part, respectively arranged inside and outside the cavity, and wherein a channel of the read transistor is formed in the inner part and electrically connected to the first read address line by the outer part.

5. The interconnect stack according to claim 4, wherein the inner part has a bowl shape that conforms to the shape of the sidewall of the cavity at the level of the channel of the read transistor and defines, with the bottom and the sidewall of the cavity, a closed volume, referred to as a separation volume, arranged facing the channel of the write transistor.

6. The interconnect stack according to claim 5, wherein the gate of the read transistor extends continuously over the sidewall of the cavity so as to form a ribbon wound about itself.

7. The interconnect stack according to claim 5, further comprising a second read address line extending parallel to the main plane, electrically connected to the channel of the read transistor by the inner part and a central via passing through an opening made in the first read address line.

8. The interconnect stack according to claim 7, wherein the first read address line is in contact with the outer part on an electrical contact area thereof, surrounding the cavity.

9. The interconnect stack according to claim 4, wherein a source and a drain of the read transistor are formed in two separate regions of the outer part, separated from each other by the inner part, and wherein the gate of the read transistor coats the bottom of the cavity.

10. The interconnect stack according to claim 9, wherein a source of the write transistor is a region of the first conformal active portion extending continuously over the sidewall of the cavity so as to form a ribbon wound about itself.

11. The interconnect stack according to claim 1, wherein the write transistor is a ferroelectric field-effect transistor.

12. A method for manufacturing an interconnect stack according to claim 1, comprising the following steps:
o providing an intermediate structure comprising a first conductive line and a second conductive line extending in separate parallel planes of the intermediate structure,
o forming the cavity in the intermediate structure, through the first conductive line,
o conformally depositing a first conformal dielectric layer on the sidewall and bottom of the cavity,
o conformally depositing a first conformal semiconductor layer on the first conformal dielectric layer,
o locally removing the first conformal semiconductor layer to leave a residual portion facing the bottom and the sidewall of the cavity forming the first conformal active portion,
o forming the channel of the write transistor in the first conformal active portion facing the first conductive line,
o forming the gate of the read transistor in the first conformal active portion.

13. The manufacturing method according to claim 12, wherein the step of forming the cavity comprises the following sub-steps:
o etching an opening through the first conductive line extending depthwise into the intermediate structure from an upper face thereof,
and wherein the first conformal dielectric layer is etched anisotropically before the step of conformally depositing the first conformal semiconductor layer in order to leave a residual portion protected by the lateral recess thus forming a gate dielectric of the write transistor.

14. The manufacturing method according to claim 13, wherein the cavity results from the etching of the opening and of the lateral recess, the method further comprising the following steps:
o depositing a filler material into the cavity, so as to cover the channel of the write transistor,
o partially etching the filler material to retain a separation volume facing the channel of the write transistor,
o successively carrying out the conformal depositions of a second conformal dielectric layer and of a second conformal semiconductor layer in the cavity and on the separation volume,
o forming a gate dielectric and a channel of the read transistor in respective regions of the second conformal dielectric layer and of the second conformal semiconductor layer facing the sidewall of the cavity and delimited by the separation volume.

15. The manufacturing method according to claim 13, wherein the cavity results from the etching of the opening and of the lateral recess, the method further comprising the following steps:
o depositing a first planarizing layer in the cavity so as to cover it,
o etching a secondary cavity crossing the first planarizing layer from one end to the other to reach the bottom of the cavity,
o conformally depositing a second conformal semiconductor layer on an upper face of the first planarizing layer, in the secondary cavity and on the bottom of the cavity,
o delimiting, by etching, a second conformal active portion in the second conformal semiconductor layer extending continuously between two regions of the second conformal semiconductor layer located on either side of the bottom of the cavity, to receive therein, respectively, a source and a drain of the read transistor.
